(19) United States
(12) Patent Application Publication
(10) Pub. No.: US 2025/0022903 A1
(43) Pub. Date: Jan. 16, 2025

(54) IMAGING APPARATUS AND CAMERA SYSTEM

(71) Applicant: Panasonic Intellectual Property Management Co., Ltd., Osaka (JP)

(72) Inventors: HIDENARI KANEHARA, Kyoto (JP); YOSHIHIRO SATO, Osaka (JP)

(21) Appl. No.: 18/903,037

(22) Filed: Oct. 1, 2024

Related U.S. Application Data
(63) Continuation of application No. PCT/JP2023/000307, filed on Jan. 10, 2023.

(30) Foreign Application Priority Data
Apr. 15, 2022 (JP) 2022-067959

(51) Int. Cl. H01L 27/146

(52) U.S. Cl. CPC H01L 27/14636; H01L 27/14603

(57) ABSTRACT

An imaging apparatus includes a semiconductor substrate; a wiring layer located on the semiconductor substrate and including wiring lines; pixel electrodes each located on the wiring layer and having one-to-one correspondence to each of the pixels; a shield electrode located on the wiring layer and disposed between the pixel electrodes; a counter electrode located above the pixel electrodes and the shield electrode; and a photoelectric conversion layer located between the pixel electrodes and the shield electrode and the counter electrode. The wiring layer includes a shield wiring line, and FD wiring lines connected respectively to the pixel electrodes. There is a one-to-one correspondence between each of the FD wiring lines and each of the pixel electrodes. The shield wiring line is connected to the shield electrode. The shield wiring line includes openings each overlapping with at least one of the FD wiring lines in a plan view.

### BACKGROUND

### 1. Technical Field

The present disclosure relates to an imaging apparatus and a camera system.

### 2. Description of the Related Art

Recently, in the field of imaging apparatuses such as CCD (Charge Coupled Device) image sensors and CMOS (Complementary MOS) image sensors, proposals have been presented for suppressing color mixture between mutually adjacent pixels. For example, an imaging apparatus capable of suppressing color mixture between mutually adjacent pixels by providing a shield electrode between the mutually adjacent pixels is disclosed in Japanese Unexamined Patent Application Publication No. 2020-77848.

### SUMMARY

An imaging apparatus that achieves a noise reduction is demanded.

In one general aspect, the techniques disclosed here provides the following imaging apparatus that has a plurality of pixels. The imaging apparatus includes a semiconductor substrate, a wiring layer, a plurality of pixel electrodes, a shield electrode, a counter electrode, and a photoelectric conversion layer. The wiring layer is located on the semiconductor substrate and includes an insulation layer and a plurality of wiring lines. Each of the plurality of pixel electrodes is located on the wiring layer. There is a one-to-one correspondence between each of the plurality of pixel electrodes and each of the plurality of pixels. The shield electrode is located on the wiring layer and is disposed between the plurality of pixel electrodes. The counter electrode is located above the plurality of pixel electrodes and the shield electrode. The photoelectric conversion layer is located between (A) the plurality of pixel electrodes and the shield electrode and (B) the counter electrode. The wiring layer includes a first wiring line, which includes a mesh structure portion, and a plurality of second wiring lines connected respectively to the plurality of pixel electrodes. There is a one-to-one correspondence between each of the plurality of second wiring lines and each of the plurality of pixel electrodes. The first wiring line is connected to the shield electrode. The mesh structure portion includes a plurality of openings each of which overlaps with at least one of the plurality of second wiring lines in a plan view.

A comprehensive or specific aspect of the present disclosure may be embodied in the form of an element, a device, or an apparatus. A comprehensive or specific aspect of the present disclosure may be embodied in the form of any combination of an element, a device, and an apparatus.

One aspect of the present disclosure makes it possible to provide an imaging apparatus that achieves a noise reduction.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a diagram illustrating an example of the configuration of an imaging apparatus according to a first embodiment;

FIG. 2 is a diagram illustrating an example of the circuit configuration of a pixel according to the first embodiment;

FIG. 3A is a plan view illustrating the layout of electrodes of pixels according to the first embodiment;

FIG. 3B is a plan view illustrating the layout of wiring lines of the pixels according to the first embodiment;

FIG. 3C is another plan view illustrating the layout of wiring lines of the pixels according to the first embodiment;

FIG. 4 is a cross-sectional view illustrating the structure of a pixel according to the first embodiment;

FIG. 5A is a plan view illustrating the layout of electrodes of pixels according to a first variation example of the first embodiment;

FIG. 5B is a plan view illustrating the layout of wiring lines of the pixels according to the first variation example of the first embodiment;

FIG. 5C is another plan view illustrating the layout of wiring lines of the pixels according to the first variation example of the first embodiment;

FIG. 6 is a cross-sectional view illustrating the structure of a pixel according to the first variation example of the first embodiment;

FIG. 7A is a plan view illustrating the layout of electrodes of pixels according to a second variation example of the first embodiment;

FIG. 7B is a plan view illustrating the layout of wiring lines of the pixels according to the second variation example of the first embodiment;

FIG. 7C is another plan view illustrating the layout of wiring lines of the pixels according to the second variation example of the first embodiment;

FIG. 8A is a plan view illustrating the layout of electrodes of pixels according to a third variation example of the first embodiment;

FIG. 8B is a plan view illustrating the layout of wiring lines of the pixels according to the third variation example of the first embodiment;

FIG. 8C is another plan view illustrating the layout of wiring lines of the pixels according to the third variation example of the first embodiment;

FIG. 9A is a plan view illustrating the layout of electrodes of pixels according to a fourth variation example of the first embodiment;

FIG. 9B is a plan view illustrating the layout of wiring lines of the pixels according to the fourth variation example of the first embodiment;

FIG. 9C is another plan view illustrating the layout of wiring lines of the pixels according to the fourth variation example of the first embodiment;

FIG. 9D is still another plan view illustrating the layout of wiring lines of the pixels according to the fourth variation example of the first embodiment;

FIG. 10A is a plan view illustrating the layout of electrodes of pixels according to a fifth variation example of the first embodiment;

FIG. 10B is a plan view illustrating the layout of wiring lines of the pixels according to the fifth variation example of the first embodiment;

FIG. 10C is another plan view illustrating the layout of wiring lines of the pixels according to the fifth variation example of the first embodiment;

FIG. 11A is a plan view illustrating the layout of electrodes of pixels according to a sixth variation example of the first embodiment;

FIG. 11B is a plan view illustrating the layout of wiring lines of the pixels according to the sixth variation example of the first embodiment;

FIG. 11C is another plan view illustrating the layout of wiring lines of the pixels according to the sixth variation example of the first embodiment;

FIG. 12 is a diagram illustrating an example of the circuit configuration of a unit pixel according to a second embodiment;

FIG. 13A is a plan view illustrating the layout of electrodes of unit pixels according to the second embodiment;

FIG. 13B is a plan view illustrating the layout of wiring lines of the unit pixels according to the second embodiment;

FIG. 14 is a cross-sectional view illustrating the structure of a unit pixel according to the second embodiment;

FIG. 15A is a plan view illustrating the layout of electrodes of unit pixels according to a first variation example of the second embodiment;

FIG. 15B is a plan view illustrating the layout of wiring lines of the unit pixels according to the first variation example of the second embodiment;

FIG. 16A is a plan view illustrating the layout of electrodes of unit pixels according to a second variation example of the second embodiment;

FIG. 16B is a plan view illustrating the layout of wiring lines of the unit pixels according to the second variation example of the second embodiment;

FIG. 17A is a plan view illustrating the layout of electrodes of unit pixels according to a third variation example of the second embodiment;

FIG. 17B is a plan view illustrating the layout of wiring lines of the unit pixels according to the third variation example of the second embodiment;

FIG. 18 is a cross-sectional view illustrating the structure of a unit pixel according to the third variation example of the second embodiment; and

FIG. 19 is a block diagram that illustrates an example of the configuration of a camera system according to a third embodiment.

### DETAILED DESCRIPTIONS

### Underlying Knowledge Forming Basis of the Present Disclosure

The inventors of the present application discovered an issue that, due to coupling of a wiring line connected to a shield electrode with a signal line, an amplitude in potential of a signal line propagates to the shield electrode and further propagates to a pixel electrode and to a wiring line connected to the pixel electrode, and this causes shading, etc. and thus deteriorates dark current characteristics. The higher the resistance of the wiring line is, the slower the returning of the fluctuating potential is; therefore, such propagation of an amplitude in potential occurs conspicuously.

The inventors of the present application further discovered an issue that the mixing of colors between mutually adjacent pixels is caused also by coupling of wiring lines connected to mutually adjacent pixel electrodes.

The inventors of the present application studied this issue of noise occurrence caused by such coupling, discovered that it is possible to reduce the shading and the color mixture between mutually adjacent pixels by improving the shapes and layout of wiring lines connected to the shield electrode, and thus arrived at an idea of the configuration of the present disclosure.

An imaging apparatus that achieves a noise reduction, etc. is provided by the present disclosure.

A certain aspect of the present disclosure includes, for example, the following configuration.

An imaging apparatus according to an aspect of the present disclosure is as follows. The imaging apparatus has a plurality of pixels. The imaging apparatus includes a semiconductor substrate, a wiring layer, a plurality of pixel electrodes, a shield electrode, a counter electrode, and a photoelectric conversion layer. The wiring layer is located on the semiconductor substrate and includes an insulation layer and a plurality of wiring lines. Each of the plurality of pixel electrodes is located on the wiring layer. There is a one-to-one correspondence between each of the plurality of pixel electrodes and each of the plurality of pixels. The shield electrode is located on the wiring layer and is disposed between the plurality of pixel electrodes. The counter electrode is located above the plurality of pixel electrodes and the shield electrode. The photoelectric conversion layer is located between (A) the plurality of pixel electrodes and the shield electrode and (B) the counter electrode. The wiring layer includes a first wiring line, which includes a mesh structure portion, and a plurality of second wiring lines connected respectively to the plurality of pixel electrodes. There is a one-to-one correspondence between each of the plurality of second wiring lines and each of the plurality of pixel electrodes. The first wiring line is connected to the shield electrode. The mesh structure portion includes a plurality of openings each of which overlaps with at least one of the plurality of second wiring lines in a plan view.

According to this configuration, since the opening overlaps with the second wiring connected to the pixel electrode, the mesh structure portion, which forms the opening, of the first wiring line surrounds the second wiring line. Consequently, the first wiring line is disposed between the second wiring lines of mutually adjacent pixels, making it possible to suppress coupling of the second wiring lines of the mutually adjacent pixels and suppress electric color mixture between the mutually adjacent pixels. Moreover, since the shield electrode is connected to the first wiring line that offers a low resistance by including the mesh structure portion, it is possible to suppress the resistance of the shield electrode and the first wiring line to be low. Consequently, it is possible to suppress shading, etc. arising from coupling, etc. of the shield electrode and the first wiring line with the signal line, etc. included in the imaging apparatus, thereby obtaining good dark current characteristics. Specifically, since the resistance of the shield electrode and the first wiring line is low, even if an amplitude in the potential of the signal line, etc. propagates to the shield electrode and the first wiring line due to the coupling with the signal line, etc. whose potential fluctuates, a quick return is achieved in potential fluctuations at the shield electrode and the first wiring line. Therefore, it is possible to suppress shading arising from the propagation of the potential fluctuations at the shield electrode and the first wiring line to the pixel electrode and the second wiring line.

With the above configuration, a noise-reduced imaging apparatus is realized.

Additionally, for example, there may be a one-to-one correspondence between each of the plurality of openings and each of the plurality of pixels.

Since the second wiring line connected to the pixel electrode of each pixel is surrounded by the mesh structure portion, which forms the opening, this makes it possible to suppress coupling of the second wiring lines of all mutually adjacent pixels of the plurality of pixels and suppress electric color mixture between the mutually adjacent pixels.

Additionally, for example, the plurality of pixels may include a plurality of pixel blocks each comprised of two or more pixels among the plurality of pixels, and there may be a one-to-one correspondence between each of the plurality of openings and each of the plurality of pixel blocks.

Since this makes it possible to increase the size of the opening, it is possible to increase the freedom of a wiring layout inside the opening. For example, it is possible to dispose a part of the signal line, etc. inside the opening and thus to reduce noise by lowering the resistance of the signal line, etc.

Additionally, for example, the mesh structure portion may overlap at least partially with the shield electrode in a plan view.

Since this makes it possible to make the connection distance between the shield electrode and the mesh structure portion shorter, it is possible to further lower the resistance of the shield electrode and the first wiring line.

Additionally, for example, the first wiring line may be connected to the shield electrode in each of the plurality of pixels.

Since this increases the places of connection of the shield electrode and the first wiring line, it is possible to further lower the resistance of the shield electrode and the first wiring line.

Additionally, for example, an electrical resistivity of a material of which the first wiring line is made may be lower than an electrical resistivity of a material of which the shield electrode is made.

This makes it possible to further lower the resistance of the first wiring line.

Additionally, for example, the plurality of pixels may include a first pixel, the wiring layer may include a first signal line connected to the first pixel, and at least a part of the mesh structure portion may be located at a level that is above a level of the first signal line in the wiring layer.

Since at least a part of the mesh structure portion of the first wiring line connected to the shield electrode is formed above the first signal line, this makes it possible to make the connection of the shield electrode and the first wiring line compact and increase the freedom of a wiring layout at the lower side.

Additionally, for example, the plurality of pixels may include a first pixel, the wiring layer may include a first signal line connected to the first pixel, and at least a part of the mesh structure portion may be located at a level that is below a level of the first signal line in the wiring layer.

This makes it possible to make the distance between the first signal line and the semiconductor substrate longer by forming the first signal line above at least a part of the mesh structure portion. For this reason, it is possible to reduce the influence of fluctuations in the potential of the first signal line on circuitry such as transistors, etc. provided on the semiconductor substrate and thus to reduce noise.

Additionally, for example, the plurality of pixels may include a first pixel, the wiring layer may include a first signal line connected to the first pixel, and at least a part of the mesh structure portion may be located at a same level as the first signal line in the wiring layer.

This makes it possible to suppress coupling of the first signal line with another signal line by the mesh structure portion and thus to reduce noise.

Additionally, for example, a part of the mesh structure portion and another part of the mesh structure portion may be located at levels different from each other in the wiring layer.

This makes it possible to increase the freedom of a wiring layout because the mesh structure portion does not have a closed structure in one level. For example, it becomes easier to form a wiring layout that can reduce noise by reducing the resistance of wiring lines.

Additionally, for example, the plurality of pixels may include a first pixel and a second pixel, the wiring layer may include a first signal line connected to the first pixel and a second signal line located at a same level as the first signal line and connected to the second pixel, the first wiring line may include a first portion located at the same level as the first signal line and the second signal line, and the first portion may be located between the first signal line and the second signal line.

This makes it possible to suppress coupling of the first signal line with the second signal line by the first portion of the first wiring line and thus to reduce noise.

Additionally, for example, the plurality of pixels may include a first pixel, the wiring layer may include a first signal line located at a same level as a part of the second wiring line and connected to the first pixel, the first wiring line may include a second portion located at the same level as the first signal line and the part of the second wiring line, and the second portion may be located between the first signal line and the part of the second wiring line.

This makes it possible to suppress coupling of the first signal line with the second wiring line by the second portion of the first wiring line and thus to reduce noise.

Additionally, for example, the plurality of pixels may include a first pixel and a second pixel, the plurality of pixel electrodes may include a first pixel electrode corresponding to the first pixel and a second pixel electrode corresponding to the second pixel, and an area of the first pixel electrode may be larger than an area of the second pixel electrode in a plan view.

This makes it possible to realize an imaging apparatus that reduces noise, and offers different sensitivities of the first pixel and the second pixel by making the areas of the first pixel electrode and the second pixel electrode different from each other.

Additionally, for example, in a plan view, a ratio of the area of the first pixel electrode to the area of the second pixel electrode may be greater than a ratio of an area of an opening corresponding to the first pixel among the plurality of openings to an area of an opening corresponding to the second pixel among the plurality of openings.

Since this increases the size of the opening overlapping with the second wiring line connected to the second pixel electrode whose area is smaller than that of the first pixel electrode, it is possible to increase the freedom of the layout of the second wiring line.

With reference to the drawings, embodiments of the present disclosure will now be described in detail.

Every embodiment described below discloses general or specific examples. Numerical values, shapes, components, positions and connections of components, steps, the orders of steps, etc. disclosed in the embodiments below are just examples and, as such, shall not be construed to limit the scope of the present disclosure. Various modes described in this specification can be combined with one another unless they are mutually contradictory. Among the components described in the embodiments below, those that are not recited in any independent claim are non-indispensable components. In the description below, the same reference signs will be assigned to components that have substantially the same function, and an explanation thereof will sometimes be omitted.

Each drawing depicts a schematic view and is not necessarily exact. Therefore, for example, the drawings are not necessarily mutually in concordance in terms of scale, etc.

In this specification, each term such as “equal” expressing a relationship between elements, each term such as “square” or “circle” expressing a shape, and each numerical range does not necessarily have a strict meaning; that is, the meaning of each of these terms, ranges, etc. encompasses a range deemed as being substantially equivalent, for example, a range allowing some percent of a margin of difference.

In this specification, the terms “above” and “below” do not refer to an upward direction (perpendicularly above) and a downward direction (perpendicularly below) in space recognition in an absolute sense but are used for defining a relative positional relation based on a layering order in a layered structure. Specifically, the light receiving side of an imaging apparatus is defined as “above”, and the side that is the opposite of the light receiving side is defined as “below”. The “upper surface” and “lower surface” of each member are also defined similarly; that is, the surface facing the light receiving side of the imaging apparatus is defined as “upper surface”, and the opposite surface facing away from the light receiving side is defined as “lower surface”. The terms “above”, “below”, “upper surface”, “lower surface”, and the like will be used just for defining the mutual arrangement of components and are not intended to limit their attitudes during use of the imaging apparatus. The terms “above” and “below” will be used not only in a case where two components are disposed with a space therebetween and another component is present therebetween but also in a case where two components are disposed in contact with each other. In this specification, the term “plan view” refers to a view taken in a direction perpendicular to a semiconductor substrate.

### FIRST EMBODIMENT

First, a configuration of an imaging apparatus according to a first embodiment will now be described.

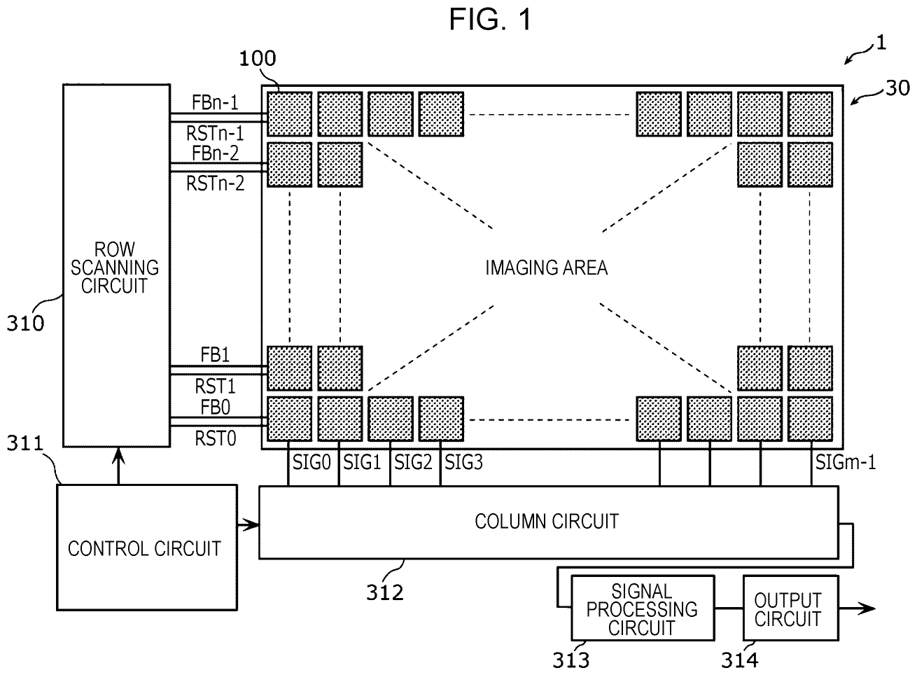

FIG. 1 is a diagram illustrating an example of the configuration of an imaging apparatus 1 according to the present embodiment. As illustrated in FIG. 1, the imaging apparatus 1 includes a pixel array 30, which includes a plurality of pixels 100, and peripheral circuitry. The pixels 100 constitute an imaging area by being arranged in two dimensions on a semiconductor substrate, for example. In the example illustrated in FIG. 1, the pixels 100 are arranged in a matrix made up of n rows and m columns, where each of n and m is an integer that is greater than or equal to 1 and where m+n≥3. In the present embodiment, each of the plurality of pixels 100 is a unit pixel where a piece of image data such as a luminance value is generated on the basis of an output signal.

In the illustrated example, the center of each pixel 100 is located at a lattice point of a square lattice. Of course, the arrangement of the pixels 100 is not limited to the illustrated example; for example, the plurality of pixels 100 may be arranged such that the center of each of them is located at a lattice point of a triangular lattice, a hexagonal lattice, or the like. The plurality of pixels 100 may be arranged in one dimension. That is, the arrangement of the pixels 100 can be in n rows and one column, or in one row and m columns. In this case, it is possible to use the imaging apparatus 1 as a line sensor.

In the configuration illustrated as an example in FIG. 1, the peripheral circuitry includes a row scanning circuit 310, a column circuit 312, a signal processing circuit 313, an output circuit 314, and a control circuit 311. The peripheral circuitry may be disposed on the semiconductor substrate on which the pixel array 30 is formed. Alternatively, a part of the peripheral circuitry may be disposed on another substrate.

The row scanning circuit 310 is connected to each reset control line RSTi and each feedback control line FBi. The reset control line RSTi and the feedback control line FBi are provided correspondingly for each row of the pixel array 30. That is, among the plurality of pixels 100, one or more pixels 100 belonging to the i-th row are connected to the reset control line RSTi and the feedback control line FBi, where i=0 to n−1.

The row scanning circuit 310 is connected to each address control line SEL, which is not illustrated in FIG. 1 and will be described later. Similarly to the reset control line RSTi and the feedback control line FBi, the address control line SEL is also provided correspondingly for each row of the pixel array 30, and is connected to the one or more pixels 100 belonging to the i-th row. By applying a predetermined voltage to the address control line, the row scanning circuit 310 selects the pixels 100 on a one-row-after-another-row basis, and performs signal voltage readout operation and reset operation to be described later. The row scanning circuit 310 is also called “vertical scanning circuit”.

The column circuit 312 is connected to each vertical signal line SIGj. The vertical signal line SIGj is provided correspondingly for each column of the pixel array 30. That is, among the plurality of pixels 100, one or more pixels 100 belonging to the j-th column are connected to the vertical signal line SIGj, where j=0 to m−1. Output signals from the pixels 100 selected on a one-row-after-another-row basis by the row scanning circuit 310 are read out via the vertical signal lines SIGj to the column circuit 312. The column circuit 312 performs, for example, noise-suppression signal processing typified by correlated double sampling, analog-to-digital conversion (A/D conversion), and the like on the output signals read out of the pixels 100.

The signal processing circuit 313 performs various kinds of processing on image signals acquired from the pixels 100. In this specification, the term “image signals” refers to, among the signals read out via the vertical signal lines SIGj, output signals used for forming an image. In the present embodiment, one unit pixel is configured as the pixel 100 that is one cell. The reading of image signals from the pixels 100 is performed by the column circuit 312. The signal processing circuit 313 forms an image on the basis of these signals. An output from the signal processing circuit 313 is read to the outside of the imaging apparatus 1 via the output circuit 314. Though a detailed description will be given later, a unit pixel may include a first imaging cell that is a high-sensitivity cell and a second imaging cell that is a low-sensitivity high-saturation cell. In a case where a unit pixel has a dual-cell structure, the reading of a high-sensitivity image signal from the first imaging cell and the reading of a low-sensitivity image signal from the second imaging cell are performed. Based on the high-sensitivity image signal and the low-sensitivity image signal, the signal processing circuit 313 forms a wide dynamic range image having a wider dynamic range. For example, for each of the plurality of unit pixels, based on at least one of the high-sensitivity image signal outputted from the first imaging cell or the low-sensitivity image signal outputted from the second imaging cell that are included in one unit pixel, the signal processing circuit 313 performs processing of generating a piece of image data such as a luminance value.

The control circuit 311 receives, for example, command data, clocks, etc. given from the outside of the imaging apparatus 1, and performs overall control on the imaging apparatus 1. The control circuit 311 includes, for example, a timing generator, and supplies drive signals to the row scanning circuit 310, the column circuit 312, etc.

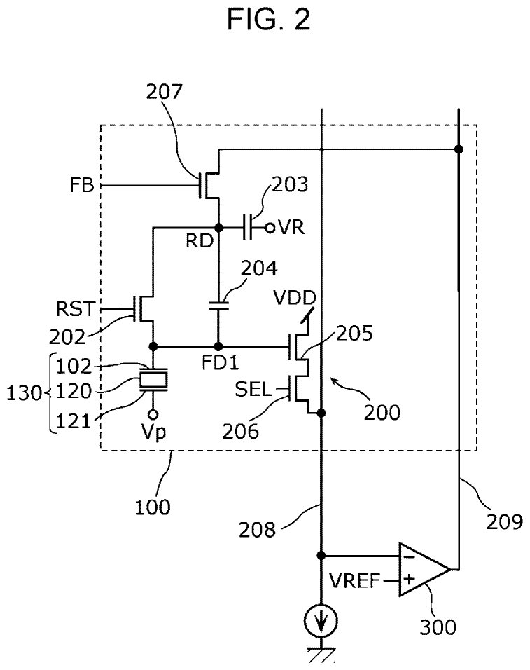

FIG. 2 is a diagram illustrating an example of the circuit configuration of the pixel 100 according to the present embodiment.

The pixel 100 includes a photoelectric conversion unit 130, which converts light into an electric signal, and a detection circuit 200, which is electrically connected to the photoelectric conversion unit 130 and reads out the electric signal generated at the photoelectric conversion unit 130. The photoelectric conversion unit 130 generates an electric signal by using light incident on a photosensitive region. The photoelectric conversion unit 130 includes a photoelectric conversion layer 120 formed of, for example, an organic material or an inorganic material such as amorphous silicon. In the description below, it is assumed by way of example that the photoelectric conversion unit 130 has a multilayer structure including the photoelectric conversion layer 120.

The photoelectric conversion unit 130 is provided on a substrate on which an amplification transistor 205 is disposed. The substrate is, for example, a semiconductor substrate. The photoelectric conversion unit 130 includes a pixel electrode 102, a counter electrode 121, and the photoelectric conversion layer 120 disposed between the pixel electrode 102 and the counter electrode 121. For example, the pixel electrode 102 is provided in each of the plurality of pixels 100. That is, the imaging apparatus 1 includes a plurality of pixel electrodes 102, and there is a one-to-one correspondence between each of the plurality of pixel electrodes 102 and each of the plurality of pixels 100. For example, two pixels 100 located adjacent to each other are electrically separated by providing a gap between them. The pixel electrode 102 is connected to a charge storage node FD1. Another name for the charge storage node is “floating diffusion node”. The counter electrode 121 is an electrode disposed on the light-receiving-side surface of the photoelectric conversion layer 120, and is formed of a transparent conductive material such as ITO (Indium Tin Oxide). When the imaging apparatus 1 is operated, a predetermined voltage Vp is applied to the counter electrode 121. The counter electrode 121 and the photoelectric conversion layer 120 may be formed in such a way as to be shared by all of the plurality of pixels 100, or may be formed for each pixel block made up of a few or several pixels 100.

By applying the voltage Vp to the counter electrode 121, it is possible to trap, by the pixel electrodes 102, either one of holes and electrons of hole-electron pairs generated at the photoelectric conversion layer 120 through photoelectric conversion. In a case where holes are used as signal charges, for example, a voltage of 10 V or so is applied as the voltage Vp to the counter electrode 121. Setting the potential of the counter electrode 121 to be higher than the potential of the pixel electrode 102 makes it possible to accumulate holes in the charge storage node FD1. In the description below, it is assumed by way of example that holes are used as signal charges. Of course, electrons may be used as signal charges. This can be done by setting the potential of the counter electrode 121 to be lower than the potential of the pixel electrode 102.

As the voltage Vp, a common voltage for all of the plurality of pixels 100 may be supplied to each of them. Alternatively, for example, different voltages for respective pixel blocks, each of which is made up of a few or several pixels 100, may be supplied. Supplying different voltages for respective pixel blocks makes it possible to vary the sensitivity of the pixels 100.

A control terminal of the amplification transistor 205 is connected to the charge storage node FD1. The control terminal is, for example, a gate.

The detection circuit 200 includes the amplification transistor 205, a selection transistor 206, a reset transistor 202, and a bandwidth control transistor 207 that is a part of a feedback circuit.

Each of these transistors is provided on the semiconductor substrate. In the description below, unless otherwise specified, it is assumed by way of example that an N-channel MOSFET (Metal Oxide Semiconductor Field Effect Transistor) is used as each transistor. The semiconductor substrate is not limited to a substrate the entirety of which is a semiconductor. The semiconductor substrate may be an insulating substrate or the like that has a semiconductor layer on a surface in which the photosensitive region is formed.

The gate of the amplification transistor 205 is connected to the photoelectric conversion unit 130. The amplification transistor 205 amplifies the electric signal generated at the photoelectric conversion unit 130. One of the source and the drain of the amplification transistor 205 is connected to one of the source and the drain of the selection transistor 206. The other of the source and the drain of the amplification transistor 205 is connected to a power supply line via which a power supply voltage VDD is supplied.

One of the source and the drain of the selection transistor 206 is connected to one of the source and the drain of the amplification transistor 205. The other of the source and the drain of the selection transistor 206 is connected to a vertical signal line 208. The vertical signal line 208 corresponds to the vertical signal line SIGj illustrated in FIG. 1. The gate of the selection transistor 206 is controlled by means of the voltage of the address control line SEL connected to the row scanning circuit 310. The selection transistor 206 selectively outputs the signal amplified by the amplification transistor 205.

One of the source and the drain of the reset transistor 202 is connected to the charge storage node FD1. The other of the source and the drain of the reset transistor 202 is connected to a node RD. The node RD is a node formed between the bandwidth control transistor 207, a first capacitive element 203, and a second capacitive element 204. The gate of the reset transistor 202 is controlled by means of the voltage of a reset control line RST. The reset control line RST corresponds to the reset control line RSTi illustrated in FIG. 1. The reset transistor 202 resets (in other words, initializes) the charge storage node FD1 connected to the pixel electrode 102 of the photoelectric conversion unit 130.

One of the source and the drain of the bandwidth control transistor 207 is connected to the node RD. The other of the source and the drain of the bandwidth control transistor 207 is connected to a feedback line 209. The gate of the bandwidth control transistor 207 is controlled by means of the voltage of a feedback control line FB. The feedback control line FB corresponds to the feedback control line FBi illustrated in FIG. 1. The bandwidth control transistor 207 controls the bandwidth of the feedback circuit. The bandwidth control transistor 207 is disposed on a feedback path and is connected to an output terminal of an inverting amplifier 300 via the feedback line 209. A reference voltage VREF is supplied to one of two input terminals of the inverting amplifier 300, and the other of these input terminals is connected to the vertical signal line 208.

The second capacitive element 204 is electrically connected between the charge storage node FD1 and the source or the drain of the bandwidth control transistor 207. The first capacitive element 203 has a capacitance value that is greater than that of the second capacitive element 204, and is connected between the second capacitive element 204 and a reference voltage terminal VR. Each of the first capacitive element 203 and the second capacitive element 204 is, for example, an MOM (Metal-Oxide-Metal) capacitor, an MIM (Metal-Insulator-Metal) capacitor, an MOS (Metal-Oxide Semiconductor) capacitor, or a trench capacitor.

The feedback circuit includes the inverting amplifier 300 and forms a feedback path for negative feedback of kTC noise that occurs when the reset transistor 202 is turned off. Providing the inverting amplifier 300 makes it possible to increase the gain of the feedback path and enhance the effect of noise suppression.

Since the pixel 100 includes the feedback circuit, it is possible to significantly suppress the noise that occurs when the reset transistor 202 is turned off.

Note that the circuit configuration of the pixel 100 is not specifically limited. Any circuit configuration other than the circuit configuration described above, for example, a circuit configuration disclosed in Japanese Unexamined Patent Application Publication No. 2017-135696, may be employed for the pixel 100.

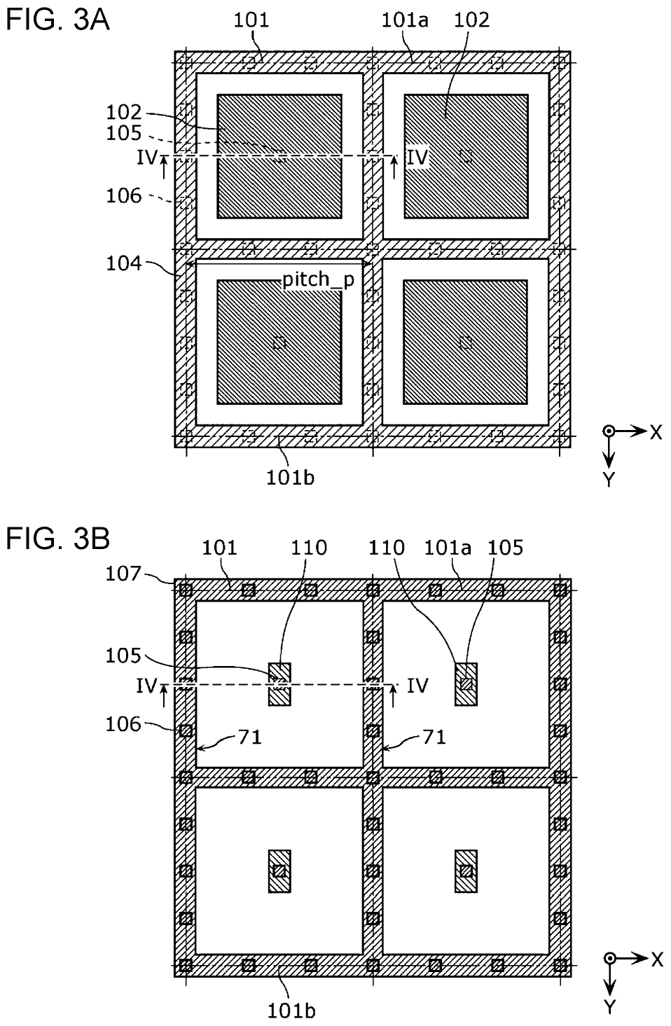

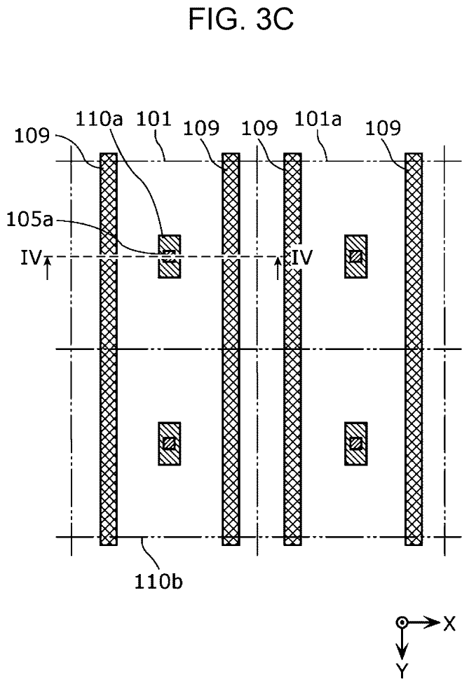

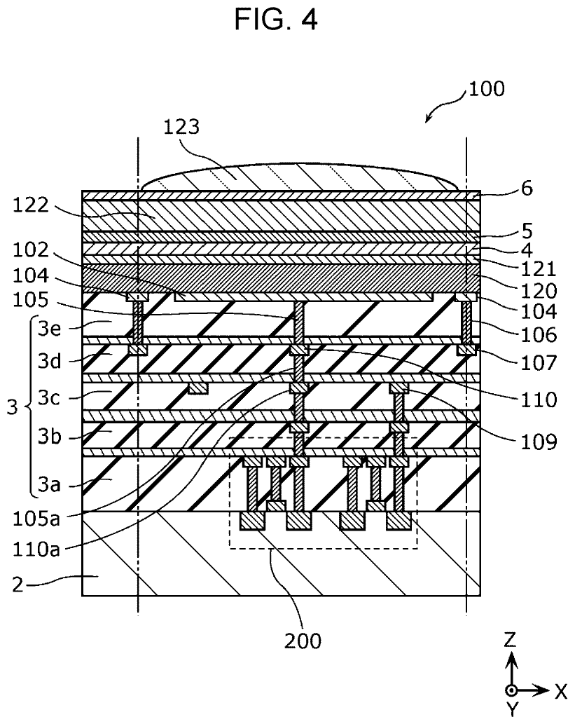

Next, a layout of electrodes, wiring lines, and the like of the pixels 100 will now be described. FIG. 3A is a plan view illustrating the layout of electrodes of the pixels 100 according to the present embodiment. Each of FIGS. 3B and 3C is a plan view illustrating the layout of wiring lines of the pixels 100 according to the present embodiment. Each of FIGS. 3A to 3C illustrates a case where electrodes or wiring lines that are located in an area corresponding to four pixels 100 are viewed in plan (or in other words, viewed from above). FIG. 4 is a cross-sectional view illustrating the structure of the pixel 100 according to the present embodiment. FIG. 4 depicts a cross section taken along the line IV-IV of each of FIGS. 3A to 3C. The cross section of an area corresponding to one pixel 100 is mainly illustrated in FIG. 4. It should be noted that, in FIGS. 3A to 4, for the purpose of easier-to-view illustration, components that are needed for description are mainly illustrated. Not all of wiring lines, circuit elements, and the like that are included in the pixel(s) 100 are illustrated therein. The same holds true for other cross-sectional views and other plan views that will be described later.

FIG. 3A is a plan view of electrodes disposed on a wiring layer 3 (specifically, a constituent layer 3e of the wiring layer 3). In FIG. 3A, contacts formed below the electrodes are indicated by broken-line illustration. Also in plan views illustrating the layout of electrodes to be described later, similarly, contacts formed below the electrodes are indicated by broken-line illustration. FIG. 3B is a plan view of wiring lines disposed on a constituent layer 3d of the wiring layer 3. FIG. 3C is a plan view of wiring lines disposed on a constituent layer 3c of the wiring layer 3. In each of FIGS. 3B and 3C, contacts formed on the wiring lines are indicated by solid-line illustration. Also in plan views illustrating the layout of wiring lines to be described later, similarly, contacts formed on the wiring lines are also illustrated.

Areas demarcated by two-dot chain lines drawn in each of FIGS. 3A to 3C are pixel areas each corresponding to the pixel 100 illustrated in FIG. 2. The pixel electrode 102 and a shield electrode 104 are provided in each pixel area. Also in subsequent drawings illustrating the layout of electrodes or wiring lines according to the present embodiment, pixel areas are demarcated off from one another by two-dot chain lines. The description below will be given with a focus on a pixel area 101 taken as a representative example of the pixel areas. The shield electrode 104 is disposed around the pixel electrode 102 provided in the pixel area 101. The shield electrode 104 surrounds the pixel electrode 102.

The shield electrode 104, which is a common electrode shared with the pixel area 101, is disposed also for pixel areas 101a and 101b located adjacent to the pixel area 101. That is, the shield electrode 104 is included in common in the pixels 100 located adjacent to one another. The shield electrode 104 may be formed as a common electrode shared by all of the pixels 100, or may be formed for each pixel block made up of a few or several pixels 100. For example, the shield electrode 104 is a single common shield electrode shared by the pixels 100 located adjacent to one another. In a plan view, the shield electrode 104 is located between the pixel electrodes 102 provided respectively in the pixels 100 located adjacent to one another.

The shield electrode 104 is, for example, connected to a non-illustrated voltage supply circuit, a non-illustrated ground, or the like, and is kept at a predetermined potential. The shield electrode 104 is electrically separated from the pixel electrodes 102. In a case where holes are used as signal charges as described earlier, setting the potential of the shield electrode 104 to be lower than the potential of the counter electrode 121 makes it possible to attract the signal charges to the shield electrode 104. Therefore, it is possible to suppress the mixing of colors between mutually adjacent pixels by the shield electrode 104 disposed between the mutually adjacent pixels. The potential of the shield electrode 104 is a fixed potential, for example, but may be varied.

As illustrated in FIGS. 3A to 4, the imaging apparatus 1 includes a semiconductor substrate 2, the wiring layer 3 located on the semiconductor substrate 2, the plurality of pixel electrodes 102 located on the wiring layer 3, the shield electrode 104 located on the wiring layer 3, the counter electrode 121 located above the plurality of pixel electrodes 102 and the shield electrode 104, the photoelectric conversion layer 120 located between “the plurality of pixel electrodes 102 and the shield electrode 104” and “the counter electrode 121”, and the detection circuits 200, which detect the potentials of the pixel electrodes 102. The imaging apparatus 1 further includes a buffer layer 4, a sealing layer 5, a color filter 122, a planarization layer 6, and micro lenses 123.

The detection circuit 200 is provided in such a way as to span across the interface between the semiconductor substrate 2 and the wiring layer 3. In FIG. 4, transistors constituting a part of the detection circuit 200 are illustrated. The pixel electrodes 102 and the shield electrode 104 are formed in the principal surface on the positive side in the Z-axis direction of, that is, in the upper surface of, the wiring layer 3. In this specification, the positive side in the Z-axis direction is defined as “above” (upper side). The pixel electrode 102 is connected to the detection circuit 200 corresponding thereto via a pixel contact 105.

The pixel electrode 102 and the shield electrode 104 are electrodes for trapping signal charges generated at the photoelectric conversion layer 120. Each of the pixel electrode 102 and the shield electrode 104 is made of a metal material such as, for example, titanium nitride (TiN). Each of the pixel electrode 102 and the shield electrode 104 may be made of copper (Cu), tungsten (W), titanium (Ti), tantalum (Ta), aluminum (Al), or a compound thereof. The layer thickness of each of the plurality of pixel electrodes 102 and the shield electrode 104 is uniform. In addition, the upper surface of the plurality of pixel electrodes 102 and the shield electrode 104 is planarized. The constituent layer 3e of the wiring layer 3 is disposed at each gap between the pixel electrodes 102 located adjacent to each other and the shield electrode 104.

The detection circuit 200 is provided correspondingly for each of the plurality of pixel electrodes 102. The detection circuit 200 detects a signal charge trapped by the pixel electrode 102 corresponding thereto, and outputs a signal voltage according to the charge. The detection circuit 200 is, for example, an MOS circuit, a TFT (Thin Film Transistor) circuit, or the like. The detection circuit 200 includes, for example, as illustrated in FIG. 2, the amplification transistor 205 whose gate is connected to the pixel electrode 102. The amplification transistor 205 outputs a signal voltage that depends on an amount of the signal charge.

The semiconductor substrate 2 is made of, for example, silicon (Si), etc.

The wiring layer 3 is formed on the semiconductor substrate 2 and includes a plurality of constituent layers 3a, 3b, 3c, 3d, and 3e, the pixel contact(s) 105, an FD wiring line(s) 110, a pixel contact(s) 105a, an FD wiring line(s) 110a, a shield contact(s) 106, a shield wiring line 107, and a signal line(s) 109. The plurality of constituent layers 3a, 3b, 3c, 3d, and 3e is layered one on another in this order as viewed from the semiconductor substrate 2. In the description below, the plurality of constituent layers 3a, 3b, 3c, 3d, and 3e will sometimes be referred to as “plurality of constituent layers 3a to 3e”. Each of the plurality of constituent layers 3a to 3e is an insulation layer made of, for example, silicon dioxide (SiO₂), etc. A plurality of wiring lines is disposed in the plurality of constituent layers 3a to 3e. Any number can be set as the number of the constituent layers included in the wiring layer 3. The five-layer structure made up of the constituent layers 3a to 3e illustrated in FIG. 4 is a non-limiting example. An insulation film(s) made of an insulating material different from that of the plurality of constituent layers 3a to 3e may be disposed between the plurality of constituent layers 3a to 3e.

The pixel electrode 102 is electrically connected to the detection circuit 200 via the pixel contact 105, the FD wiring line 110, the pixel contact 105a, and the FD wiring line 110a. In the present embodiment, a wiring line that includes the pixel contact 105, the FD wiring line 110, the pixel contact 105a, and the FD wiring line 110a is an example of a second wiring line connected to the pixel electrode 102. The wiring layer 3 includes a plurality of second wiring lines. There is a one-to-one correspondence between each of the plurality of second wiring lines and each of the plurality of pixel electrodes 102. Therefore, it can also be said that there is a one-to-one correspondence between each of the plurality of second wiring lines and each of the plurality of pixels 100.

The shield electrode 104 is connected to the shield wiring line 107 via the shield contacts 106. In the present embodiment, a wiring line that includes the shield contact 106 and the shield wiring line 107 is an example of a first wiring line connected to the shield electrode 104.

Each of the pixel contact 105, the FD wiring line 110, the pixel contact 105a, the FD wiring line 110a, the shield contact 106, and the shield wiring line 107 is formed by embedding a conductive material such as, for example, copper (Cu), tungsten (W), etc. into the wiring layer 3. The electrical resistivity of a material of which each of the pixel contact 105, the FD wiring line 110, the pixel contact 105a, the FD wiring line 110a, the shield contact 106, and the shield wiring line 107 is made is, for example, lower than the electrical resistivity of a material of which each of the pixel electrode 102 and the shield electrode 104 is made.

The photoelectric conversion layer 120 lies on the upper surface of the constituent layer 3e, on which the pixel electrodes 102 and the shield electrode 104 are disposed. The counter electrode 121, the buffer layer 4, and the sealing layer 5 are stacked in this order on the upper surface of the photoelectric conversion layer 120. The color filter 122 having a transmission wavelength range corresponding to each pixel 100 is stacked on the upper surface of the sealing layer 5. The micro lens 123 corresponding to the pixel electrode 102 is formed on the upper surface of the color filter 122, with the planarization layer 6 disposed therebetween.

The constituent layer 3e of the wiring layer 3 is interposed between the pixel electrodes 102 located adjacent to each other and the shield electrode 104.

The photoelectric conversion layer 120 is a layer made of a photoelectric conversion material that generates a signal charge dependent on the intensity of received light. That is, the photoelectric conversion layer 120 converts light into a signal charge. The photoelectric conversion layer 120 is sandwiched between “the pixel electrode 102 and the shield electrode 104” and “the counter electrode 121”. The photoelectric conversion material is, for example, an organic semiconductor material, and includes at least one of a p-type organic semiconductor or an n-type organic semiconductor. The photoelectric conversion layer 120 is, for example, in the pixel array 30, formed as a common layer and has a uniform thickness.

The counter electrode 121 is an electrode that is opposed to the pixel electrode 102 and the shield electrode 104.

In the present embodiment, the counter electrode 121 is disposed at the side where incident light comes in to the imaging apparatus 1. The counter electrode 121 may have translucency for allowing light to enter the photoelectric conversion layer 120. A transparent conductive oxide material, for example, indium tin oxide (ITO), indium zinc oxide (IZO), or the like, may be used as the material of the counter electrode 121.

As illustrated in FIGS. 3A, 3B, and 4, the pixel contact 105 for electric connection to the charge storage node FD1 is disposed below the pixel electrode 102. The pixel contact 105 is connected to the lower surface of the pixel electrode 102. The pixel electrode 102 is connected to the FD wiring line 110 via the pixel contact 105.

The shield contact(s) 106 is disposed below the shield electrode 104. The shield contact 106 is connected to the lower surface of the shield electrode 104. The shield electrode 104 is connected to the shield wiring line 107 via the shield contacts 106 in each of the plurality of pixel areas corresponding to the plurality of pixels 100. The shield wiring line 107 overlaps at least partially with the shield electrode 104 in a plan view.

The pixel electrodes 102 are arranged as an array forming a square lattice at a pitch denoted as “pitch_p”.

The FD wiring line(s) 110 and the shield wiring line 107 are embedded in the same constituent layer 3d. The shield wiring line 107 is located at the same level as the FD wiring line 110 in the wiring layer 3. In this specification, the term “level” means a height with respect to the upper surface of the semiconductor substrate 2. For example, heights, from the upper surface of the semiconductor substrate 2, of the plurality of constituent layers 3a to 3e in which wiring lines are provided correspond to levels. For example, wiring lines, etc. embedded in the same constituent layer can be said to be located at the same level.

The shield wiring line 107 is disposed around the FD wiring line 110, and is interconnected in the vertical direction and the horizontal direction within a range of the pitch pitch_p. That is, the shield wiring line 107 has a lattice shape having the pitch pitch_p in the vertical direction and the horizontal direction in a plan view. In the present embodiment, the vertical direction is the Y-axis direction, and the horizontal direction is the X-axis direction. The vertical direction is the column direction of the pixel array 30. The horizontal direction is the row direction of the pixel array 30.

The first wiring line includes a mesh structure portion that has a pattern like the meshes of a net. The mesh structure portion includes a plurality of openings 71 in a plan view. The mesh structure portion overlaps with the area where the pixel array 30 is disposed in a plan view. In the present embodiment, the mesh structure portion is configured as the shield wiring line 107. In the example illustrated in FIG. 3B, the opening 71 is a square portion surrounded by the shield wiring line 107. The arrow indicating the opening 71 in FIG. 3B points to the contour of the opening 71. The same holds true for the subsequent drawings that follow FIG. 3B; namely, each arrow indicating an opening points to the contour of the opening.

Each of the plurality of openings 71 overlaps with the FD wiring line 110 in a plan view. It can also be said that the contour of each of the plurality of openings 71 surrounds the FD wiring line 110 in a plan view. In the present embodiment, one opening 71 overlaps with one FD wiring line 110 in a plan view. Moreover, in a plan view, one opening 71 is disposed for a pixel area inside which one FD wiring line 110 is disposed, and there is a one-to-one correspondence between each of the plurality of openings 71 and each of the plurality of pixels 100. The opening 71 corresponding to a certain pixel 100 means the opening 71 overlapping with the second wiring line corrected to the pixel electrode 102 of this certain pixel 100. The mesh structure portion may include any opening, other than the plurality of openings 71, not overlapping with the second wiring line.

As illustrated in FIGS. 3C and 4, the signal line(s) 109 and the FD wiring line(s) 110a are embedded in the same constituent layer 3c. The FD wiring line 110a is connected to the FD wiring line 110 via the pixel contact 105a.

The signal line 109 extends in the vertical direction. The wiring layer 3 includes a plurality of signal lines 109. These signal lines 109 are in parallel with one another. The signal line 109 is, for example, at least a part of the vertical signal line 208 or the feedback line 209 illustrated in FIG. 2. For example, one of two signal lines 109 that go through the pixel area 101 is at least a part of the vertical signal line 208, and the other thereof is at least a part of the feedback line 209. The signal line 109 is connected to, for example, the pixel(s) 100 corresponding to the pixel area(s) through which this signal line 109 goes. In the present embodiment, the signal line 109 that goes through the pixel area 101 is an example of a first signal line. The pixel 100 corresponding to the pixel area 101 is an example of a first pixel.

The signal line(s) 109 and the FD wiring line(s) 110a are located at the same level in the wiring layer 3. The shield wiring line 107 constituting the mesh structure portion is located at a level that is above the level of the signal line(s) 109 and the FD wiring line(s) 110a in the wiring layer 3. Since this makes the connection between the shield wiring line 107 and the shield electrode 104 compact, it is possible to increase the freedom of a wiring layout below the shield wiring line 107.

As described above, in the present embodiment, the shield wiring line 107 is disposed around the FD wiring line(s) 110, and each of the plurality of openings 71 formed by the shield wiring line 107 overlaps with the FD wiring line 110. Since the shield wiring line 107 exists between the FD wiring lines 110 of mutually adjacent pixels as described above, it is possible to suppress coupling of the FD wiring lines 110 between the mutually adjacent pixels and suppress electric color mixture. Moreover, since the shield electrode 104 is connected to the shield wiring line 107 that offers a low resistance by constituting the mesh structure portion, it is possible to suppress the resistance of the shield electrode 104 and the shield wiring line 107 inside the pixel array 30 to be low. Consequently, it is possible to suppress shading, etc. arising from coupling, etc. of the shield electrode 104 and the shield wiring line 107 with the signal line 109, thereby obtaining good dark current characteristics. Specifically, since the resistance of the shield electrode 104 and the shield wiring line 107 is low, even if an amplitude in the potential of the signal line 109 propagates to the shield electrode 104 and the shield wiring line 107 due to the coupling with the signal line 109, a quick return is achieved in potential fluctuations at the shield electrode 104 and the shield wiring line 107. Therefore, it is possible to suppress shading arising from the propagation of the potential fluctuations at the shield electrode 104 and the shield wiring line 107 to the pixel electrode 102 and the FD wiring line 110. With the present embodiment described above, the noise-reduced imaging apparatus 1 is realized.

### First Variation Example

Next, an imaging apparatus according to a first variation example of the first embodiment will now be described. In the description of the first variation example below, the point of difference from the first embodiment will be mainly described, and an explanation of the point of sameness will be omitted or simplified. The same holds true for second and subsequent variation examples to be described later. In the description of each variation example, the point of difference from the first embodiment and other variation examples will be mainly described, and an explanation of the point of sameness will be omitted or simplified.

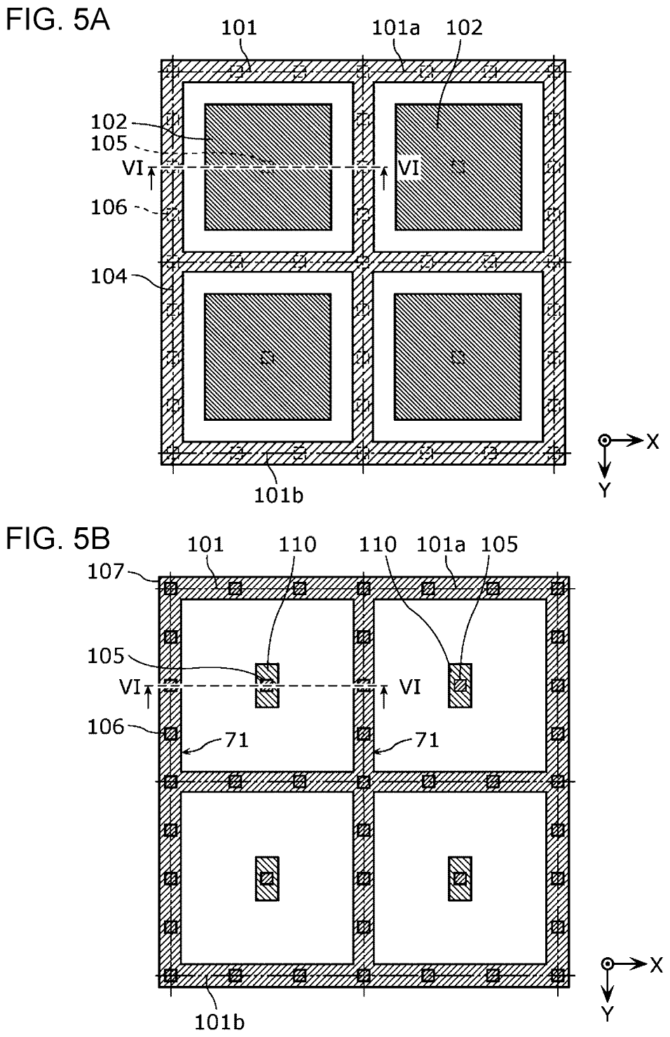

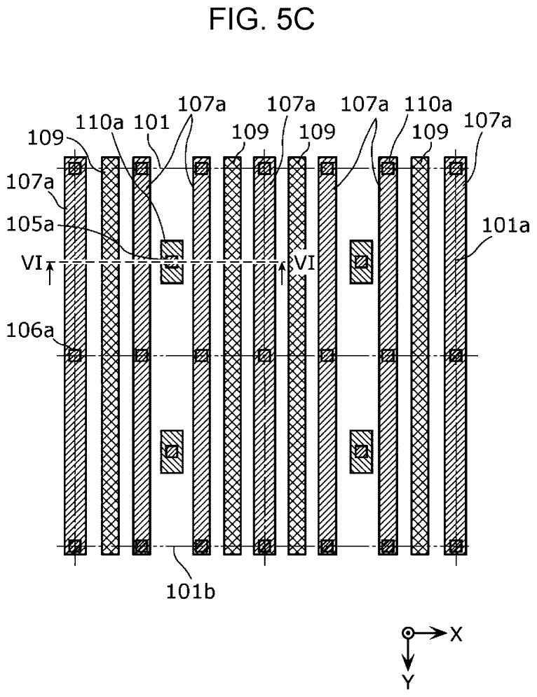

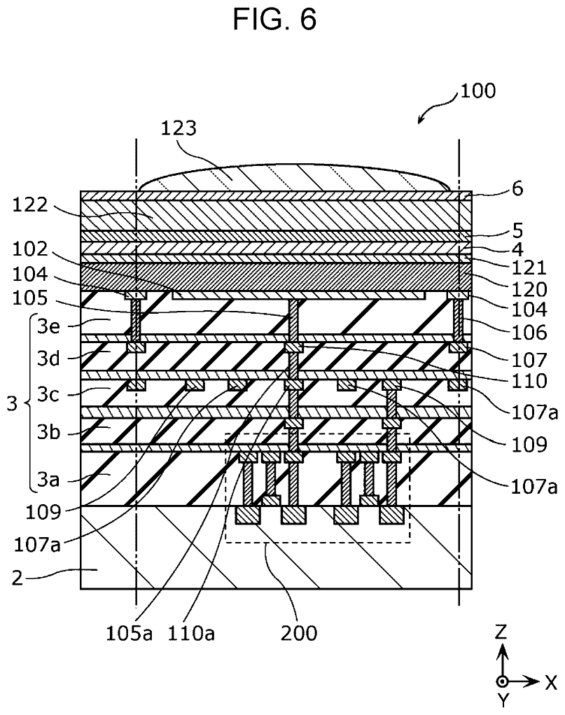

FIG. 5A is a plan view illustrating the layout of electrodes of the pixels 100 according to the present variation example. Each of FIGS. 5B and 5C is a plan view illustrating the layout of wiring lines of the pixels 100 according to the present variation example. Each of FIGS. 5A to 5C illustrates a case where electrodes or wiring lines that are located in an area corresponding to four pixels 100 are viewed in plan. FIG. 6 is a cross-sectional view illustrating the structure of the pixel 100 according to the present variation example. FIG. 6 depicts a cross section taken along the line VI-VI of each of FIGS. 5A to 5C. The cross section of an area corresponding to one pixel 100 is mainly illustrated in FIG. 6.

FIG. 5A is a plan view of electrodes disposed on the wiring layer 3 (specifically, the constituent layer 3e of the wiring layer 3). FIG. 5B is a plan view of wiring lines disposed on the constituent layer 3d of the wiring layer 3. FIG. 5C is a plan view of wiring lines disposed on the constituent layer 3c of the wiring layer 3.

As illustrated in FIGS. 5A to 6, the main difference of the present variation example from the first embodiment lies in that the wiring layer 3 further includes a shield wiring line 107a and a shield contact(s) 106a.

As illustrated in FIGS. 5C and 6, the signal line(s) 109, the FD wiring line(s) 110a, and the shield wiring line 107a are embedded in the same constituent layer 3c. The shield wiring line 107a is connected to the shield wiring line 107 via the shield contacts 106a. Since the shield wiring line 107 is connected also to the shield wiring line 107a, it is possible to further suppress the resistance of the shield electrode 104, the shield wiring line 107, and the shield wiring line 107a inside the pixel array 30 to be low. In the present variation example, a wiring line that includes the shield contact 106, the shield wiring line 107, the shield contact 106a, and the shield wiring line 107a is an example of a first wiring line connected to the shield electrode 104.

The signal line(s) 109, the FD wiring line(s) 110a, and the shield wiring line 107a are located at the same level in the wiring layer 3. The shield wiring line 107 constituting the mesh structure portion is located at a level that is above the level of the signal line(s) 109, the FD wiring line(s) 110a, and the shield wiring line 107a in the wiring layer 3.

The shield wiring line 107a is located between the signal line 109 connected to the pixel 100 corresponding to the pixel area 101 and the signal line 109 connected to the pixel 100 corresponding to the pixel area 101a located adjacent to the pixel area 101. This makes it possible to suppress coupling of the above-mentioned two signal lines 109 with each other by means of the shield wiring line 107a. Therefore, it is possible to suppress noise and obtain good dark current characteristics. In the present variation example, the signal line 109 that goes through the pixel area 101a is an example of a second signal line. The pixel 100 corresponding to the pixel area 101a is an example of a second pixel. The shield wiring line 107a disposed between the above-mentioned two signal lines 109 is an example of a first portion.

In each pixel area, the shield wiring line 107a is located between the FD wiring line 110a and the signal line 109. This enables the shield wiring line 107a to suppress coupling between the FD wiring line 110a and the signal line 109. Therefore, it is possible to suppress noise and obtain good dark current characteristics. In the present variation example, the shield wiring line 107a located between the FD wiring line 110a and the signal line 109 in the pixel area 101 is an example of a second portion.

### Second Variation Example

Next, an imaging apparatus according to a second variation example of the first embodiment will now be described.

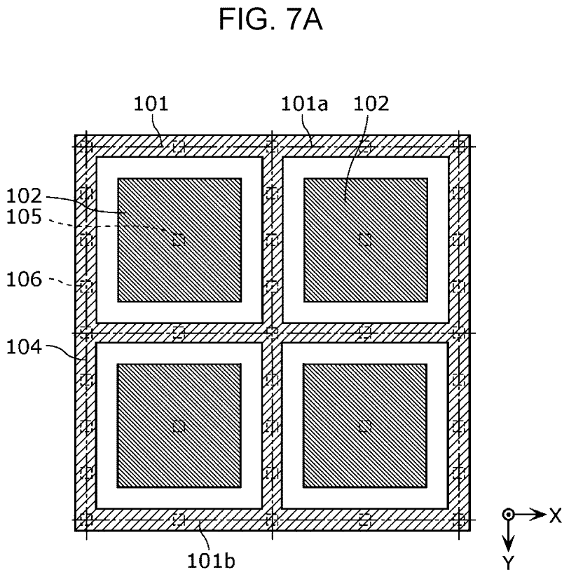

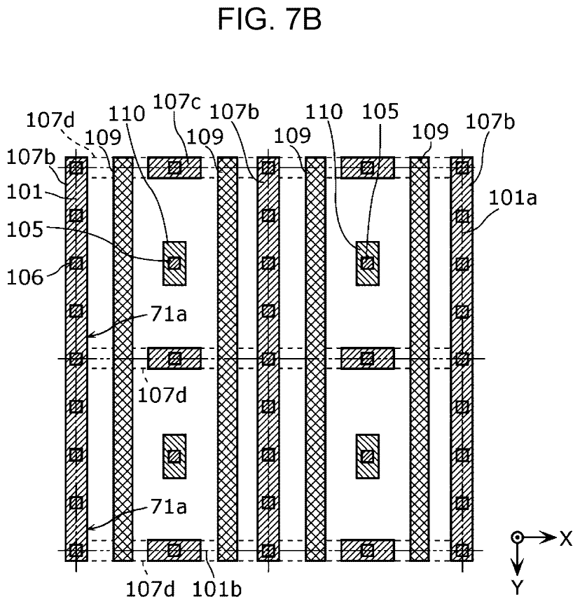

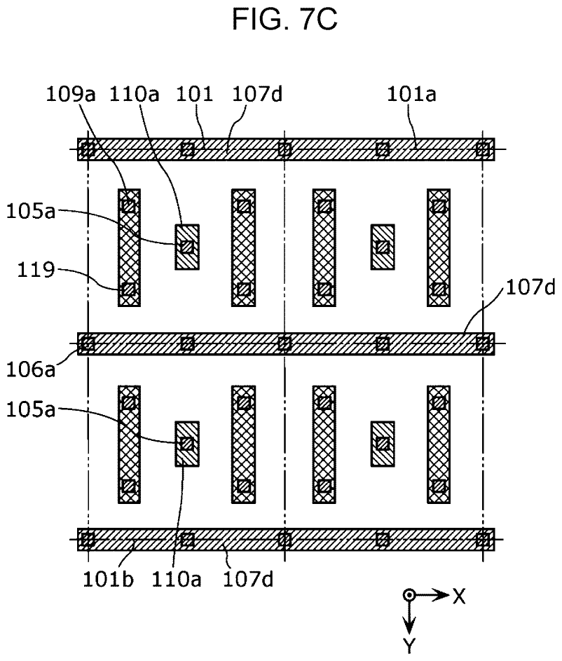

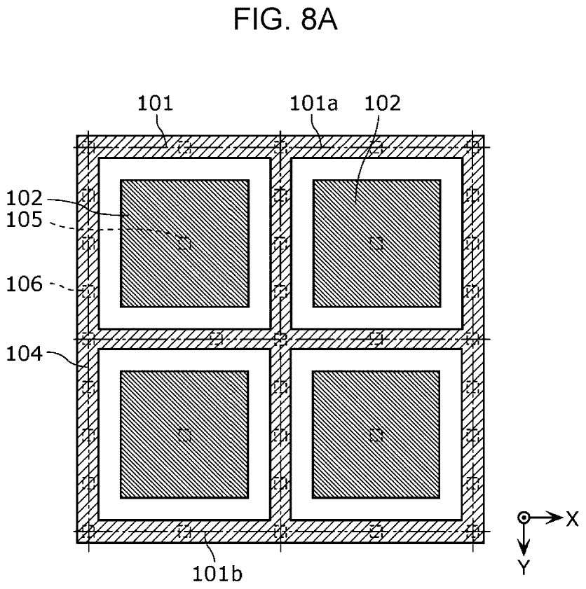

FIG. 7A is a plan view illustrating the layout of electrodes of the pixels 100 according to the present variation example. Each of FIGS. 7B and 7C is a plan view illustrating the layout of wiring lines of the pixels 100 according to the present variation example. Each of FIGS. 7A to 7C illustrates a case where electrodes or wiring lines that are located in an area corresponding to four pixels 100 are viewed in plan. FIG. 7A is a plan view of electrodes disposed on the wiring layer 3 (specifically, the constituent layer 3e of the wiring layer 3). FIG. 7B is a plan view of wiring lines disposed on the constituent layer 3d of the wiring layer 3. FIG. 7C is a plan view of wiring lines disposed on the constituent layer 3c of the wiring layer 3. In FIG. 7B, shield wiring lines 107d disposed below shield wiring lines 107b are indicated by broken-line illustration.

As illustrated in FIGS. 7A to 7C, the present variation example is different from the first embodiment in terms of the layout of wiring lines on the constituent layer 3d and the constituent layer 3c of the wiring layer 3. In the present variation example, the wiring layer 3 includes the pixel contacts 105, the FD wiring lines 110, the pixel contacts 105a, the FD wiring lines 110a, the shield contacts 106, the shield wiring lines 107b, shield wiring lines 107c, the shield contacts 106a, the shield wiring lines 107d, the signal lines 109, signal lines 109a, and signal line contacts 119.

As illustrated in FIG. 7B, the signal lines 109, the FD wiring lines 110, the shield wiring lines 107b, and the shield wiring lines 107c are embedded in the same constituent layer 3d. As illustrated in FIG. 7C, the signal lines 109a, the FD wiring lines 110a, and the shield wiring lines 107d are embedded in the same constituent layer 3c.

Each of the shield wiring line(s) 107b and the shield wiring line(s) 107c is connected to the shield electrode 104 via the shield contact(s) 106. Each of the shield wiring line(s) 107b and the shield wiring line(s) 107c is connected to the shield wiring line(s) 107d via the shield contact(s) 106a. The shield wiring line 107c extends in the horizontal direction within a range of not being in contact with any other wiring line. The shield wiring line 107b extends in the vertical direction. The shield wiring lines 107b are arranged at, for example, the pitch pitch_p described above.

The shield wiring line 107d extends in the horizontal direction. The shield wiring lines 107d are arranged at, for example, the pitch pitch_p described above. In the present variation example, a wiring line that includes the shield contact 106, the shield wiring line 107b, the shield wiring line 107c, the shield contact 106a, and the shield wiring line 107d is an example of a first wiring line connected to the shield electrode 104.

As illustrated in FIG. 7B, the first wiring line includes a mesh structure portion that has a pattern like the meshes of a net. The mesh structure portion includes a plurality of openings 71a in a plan view. In the present variation example, the mesh structure portion is comprised of the shield wiring lines 107b, the shield contacts 106a, and the shield wiring lines 107d. Each of the plurality of openings 71a overlaps with the FD wiring line 110 and the FD wiring line 110a in a plan view. In the present variation example, one opening 71a overlaps with one FD wiring line 110 and one FD wiring line 110a. One opening 71a is disposed for each one pixel area, and there is a one-to-one correspondence between each of the plurality of openings 71a and each of the plurality of pixels 100. Since the opening 71a overlaps with the FD wiring line 110 and the FD wiring line 110a as described above, the mesh structure portion suppresses coupling of the FD wiring lines 110 and the FD wiring lines 110a between the mutually adjacent pixels, making it possible to suppress electric color mixture. For example, as illustrated in FIG. 7C, since the shield wiring line 107d is disposed between the FD wiring line 110a disposed inside the pixel area 101 and the FD wiring line 110a disposed inside a pixel area 101b, it is possible to suppress coupling of the above-mentioned two FD wiring lines 110a with each other. Moreover, since the shield electrode 104 is connected to the shield wiring lines 107b and the shield wiring lines 107d that constitute the mesh structure portion, it is possible to suppress the resistance of the shield electrode 104, the shield wiring lines 107b, and the shield wiring lines 107d inside the pixel array 30 to be low. Moreover, for example, as illustrated in FIG. 7B, since the shield wiring line 107c is disposed between the FD wiring line 110 disposed inside the pixel area 101 and the FD wiring line 110 disposed inside the pixel area 101b, it is possible to suppress coupling of the above-mentioned two FD wiring lines 110 with each other.

In the present variation example, the shield wiring lines 107b, which constitute a part of the mesh structure portion, and the shield wiring lines 107d, which constitute another part of the mesh structure portion, are located at levels different from each other in the wiring layer 3. Since the mesh structure portion spans from one to another of a plurality of levels, it is possible to increase the freedom of a layout of wiring lines at each of the plurality of levels in the wiring layer 3.

As illustrated in FIG. 7B, the shield wiring lines 107b, which constitute a part of the mesh structure portion, are located at the same level as the signal lines 109 in the wiring layer 3. The shield wiring line 107b is located between the signal line 109 connected to the pixel 100 corresponding to the pixel area 101 and the signal line 109 connected to the pixel 100 corresponding to the pixel area 101a that are located adjacent to each other. This makes it possible to suppress coupling of the above-mentioned two signal lines 109 with each other by means of the shield wiring line 107b. In the present variation example, the shield wiring line 107b disposed between the above-mentioned two signal lines 109 is an example of a first portion.

As illustrated in FIG. 7C, the signal line(s) 109a is connected to the signal line(s) 109 via the signal line contacts 119. This realizes the low resistance of the signal line 109 and the signal line 109a. Consequently, it is possible to enhance signal response and reduce noise.

The shield wiring lines 107d, which constitute a part of the mesh structure portion, are located at a level that is below the level of the signal lines 109 in the wiring layer 3. Since the signal line 109 is located above the shield wiring line 107d, the distance between the semiconductor substrate 2 and the signal line 109 is long. For this reason, it is possible to reduce the influence of fluctuations in the potential of the signal line 109 on circuitry such as transistors, etc. provided on the semiconductor substrate 2 and thus to reduce noise.

### Third Variation Example

Next, an imaging apparatus according to a third variation example of the first embodiment will now be described.

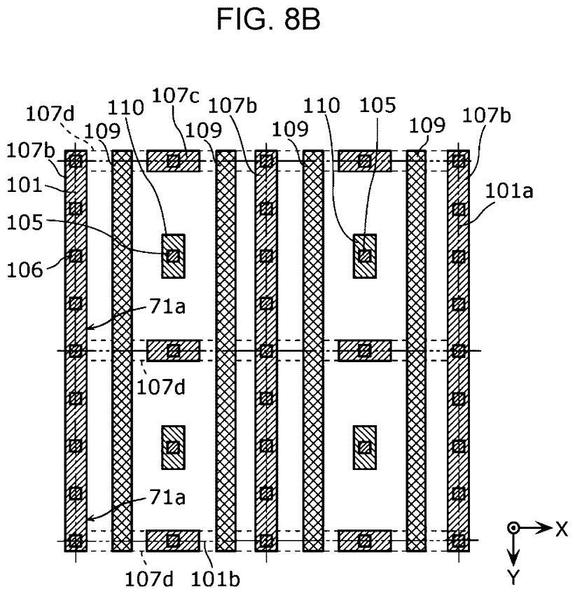

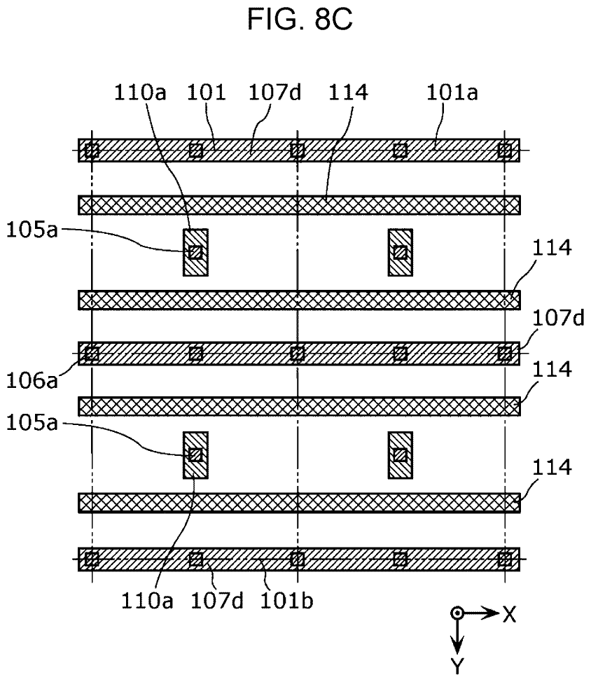

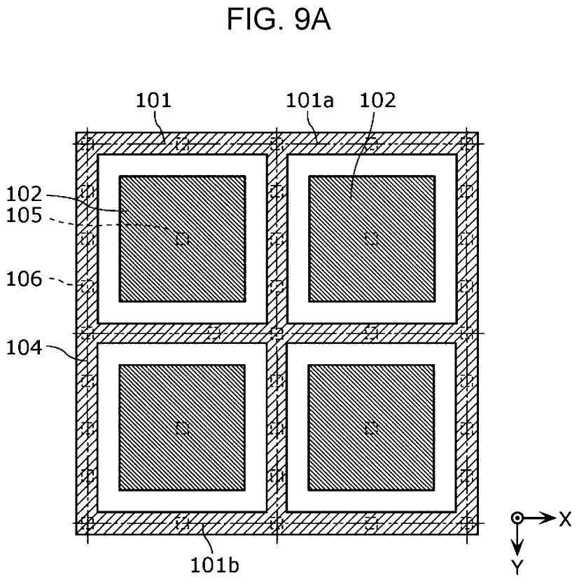

FIG. 8A is a plan view illustrating the layout of electrodes of the pixels 100 according to the present variation example. Each of FIGS. 8B and 8C is a plan view illustrating the layout of wiring lines of the pixels 100 according to the present variation example. Each of FIGS. 8A to 8C illustrates a case where electrodes or wiring lines that are located in an area corresponding to four pixels 100 are viewed in plan. FIG. 8A is a plan view of electrodes disposed on the wiring layer 3 (specifically, the constituent layer 3e of the wiring layer 3). FIG. 8B is a plan view of wiring lines disposed on the constituent layer 3d of the wiring layer 3. FIG. 8C is a plan view of wiring lines disposed on the constituent layer 3c of the wiring layer 3. In FIG. 8B, the shield wiring lines 107d disposed below the shield wiring lines 107b are indicated by broken-line illustration.

As illustrated in FIGS. 8A to 8C, the main difference of the present variation example from the second variation example of the first embodiment lies in that the wiring layer 3 includes signal lines 114 in place of the signal lines 109a.

As illustrated in FIG. 8C, the signal line(s) 114, the FD wiring line(s) 110a, and the shield wiring line(s) 107d are embedded in the same constituent layer 3c.

The signal line 114 extends in the horizontal direction. The wiring layer 3 includes a plurality of signal lines 114. These signal lines 114 are in parallel with one another. The signal line 114 is, for example, at least a part of the address control line SEL, the reset control line RST, or the feedback control line FB illustrated in FIG. 2. The signal line 114 is connected to, for example, the pixel(s) 100 corresponding to the pixel area(s) through which this signal line 114 goes.

The shield wiring lines 107d, which constitute a part of the mesh structure portion, are located at the same level as the signal lines 114 in the wiring layer 3. As described above, in the present variation example, the signal line(s) 114 is formed at the same level as the shield wiring line(s) 107d. The signal line 114 can be used for applying a control signal from the row scanning circuit 310.

The shield wiring line 107d is located between the signal line 114 connected to the pixel 100 corresponding to the pixel area 101 and the signal line 114 connected to the pixel 100 corresponding to the pixel area 101b located adjacent to the pixel area 101. This makes it possible to suppress coupling of the above-mentioned two signal lines 114 with each other by means of the shield wiring line 107d. Therefore, it is possible to suppress noise and obtain good dark current characteristics. In the present variation example, the signal line 114 that goes through the pixel area 101 is an example of a first signal line, and the signal line 114 that goes through the pixel area 101b is an example of a second signal line. The pixel 100 corresponding to the pixel area 101b is an example of a second pixel. The shield wiring line 107d disposed between the above-mentioned two signal lines 114 is an example of a first portion.

### Fourth Variation Example

Next, an imaging apparatus according to a fourth variation example of the first embodiment will now be described.

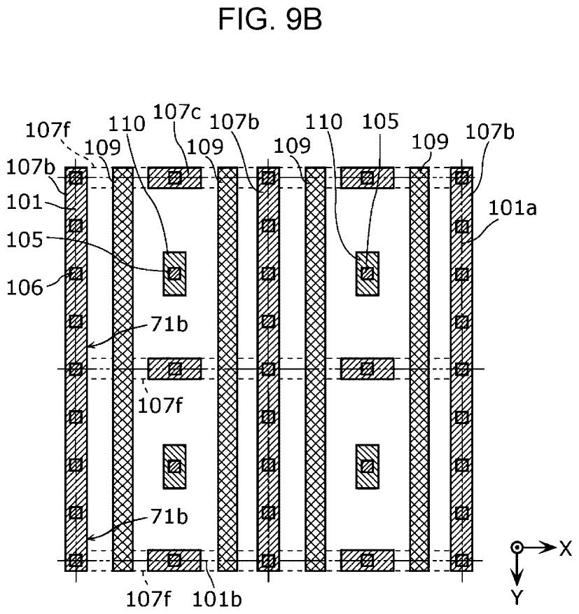

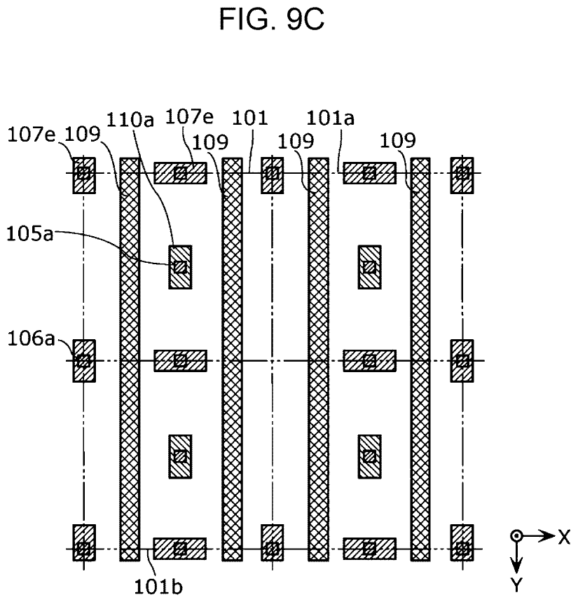

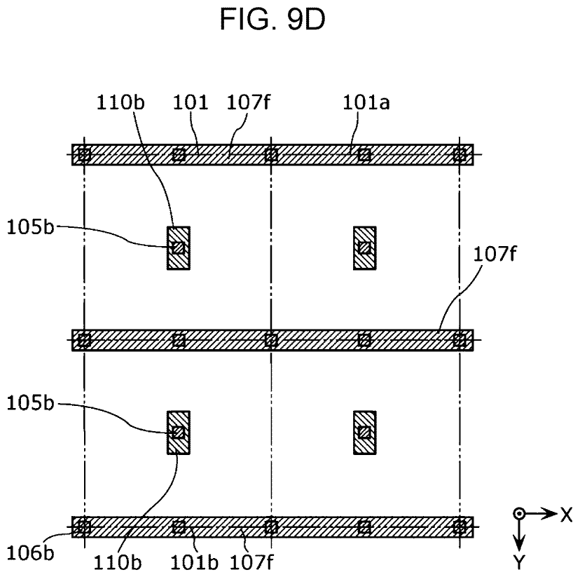

FIG. 9A is a plan view illustrating the layout of electrodes of the pixels 100 according to the present variation example. Each of FIGS. 9B to 9D is a plan view illustrating the layout of wiring lines of the pixels 100 according to the present variation example. Each of FIGS. 9A to 9D illustrates a case where electrodes or wiring lines that are located in an area corresponding to four pixels 100 are viewed in plan. FIG. 9A is a plan view of electrodes disposed on the wiring layer 3 (specifically, the constituent layer 3e of the wiring layer 3). FIG. 9B is a plan view of wiring lines disposed on the constituent layer 3d of the wiring layer 3. FIG. 9C is a plan view of wiring lines disposed on the constituent layer 3c of the wiring layer 3. FIG. 9D is a plan view of wiring lines disposed on the constituent layer 3b of the wiring layer 3. In FIG. 9B, shield wiring lines 107f disposed below the shield wiring lines 107b are indicated by broken-line illustration.

As illustrated in FIGS. 9A to 9D, the main difference of the present variation example from the second variation example of the first embodiment lies in that the wiring layer 3 includes the shield wiring lines 107f in place of the shield wiring lines 107d. In the present variation example, the wiring layer 3 includes the pixel contacts 105, the FD wiring lines 110, the pixel contacts 105a, the FD wiring lines 110a, pixel contacts 105b, FD wiring lines 110b, the shield contacts 106, the shield wiring lines 107b, the shield wiring lines 107c, the shield contacts 106a, shield wiring lines 107e, shield contacts 106b, the shield wiring lines 107f, and the signal lines 109.

As illustrated in FIG. 9C, the signal lines 109, the FD wiring lines 110a, and the shield wiring lines 107e are embedded in the same constituent layer 3c. As illustrated in FIG. 9D, the FD wiring lines 110b and the shield wiring lines 107f are embedded in the same constituent layer 3b.

The FD wiring line 110b is connected to the FD wiring line 110a via the pixel contact 105b. In the present variation example, a wiring line that includes the pixel contact 105, the FD wiring line 110, the pixel contact 105a, the FD wiring line 110a, the pixel contact 105b, and the FD wiring line 110b is an example of a second wiring line connected to the pixel electrode 102.

The shield wiring line 107e is connected to the shield wiring line 107b or the shield wiring line 107c via the shield contact 106a. The shield wiring line 107e extends in the horizontal direction within a range of not being in contact with any other wiring line. The shield wiring line 107f is connected to the shield wiring line 107e via the shield contact 106b. The shield wiring line 107f extends in the horizontal direction. The shield wiring lines 107f are arranged at, for example, the pitch pitch_p described above. In the present variation example, a wiring line that includes the shield contact 106, the shield wiring line 107b, the shield wiring line 107c, the shield contact 106a, the shield wiring line 107e, the shield contact 106b, and the shield wiring line 107f is an example of a first wiring line connected to the shield electrode 104.

As illustrated in FIG. 9B, the first wiring line includes a mesh structure portion that has a pattern like the meshes of a net. The mesh structure portion includes a plurality of openings 71b in a plan view. In the present variation example, the mesh structure portion is comprised of the shield wiring lines 107b, the shield wiring lines 107c, the shield contacts 106a, the shield wiring lines 107e, the shield contacts 106b, and the shield wiring lines 107f. In the present variation example, the mesh structure portion spans at the three constituent layers 3b to 3d. Each of the plurality of openings 71b overlaps with the FD wiring line 110 and the FD wiring line 110b in a plan view. In the present variation example, one opening 71b overlaps with one FD wiring line 110 and one FD wiring line 110b. One opening 71b is disposed for each one pixel area, and there is a one-to-one correspondence between each of the plurality of openings 71b and each of the plurality of pixels 100. Since the opening 71b overlaps with the FD wiring line 110 and the FD wiring line 110b as described above, the mesh structure portion suppresses coupling of the FD wiring lines 110 and the FD wiring lines 110b between the mutually adjacent pixels, making it possible to suppress electric color mixture. For example, as illustrated in FIG. 9D, since the shield wiring line 107f is disposed between the FD wiring line 110b disposed inside the pixel area 101 and the FD wiring line 110b disposed inside the pixel area 101b, it is possible to suppress coupling of the above-mentioned two FD wiring lines 110b with each other. Moreover, for example, as illustrated in FIG. 9B, since the shield wiring line 107c is disposed between the FD wiring line 110 disposed inside the pixel area 101 and the FD wiring line 110 disposed inside the pixel area 101b, it is possible to suppress coupling of the above-mentioned two FD wiring lines 110 with each other. Moreover, for example, as illustrated in FIG. 9C, since the shield wiring line 107e is disposed between the FD wiring line 110a disposed inside the pixel area 101 and the FD wiring line 110a disposed inside the pixel area 101b, it is possible to suppress coupling of the above-mentioned two FD wiring lines 110a with each other.

Moreover, since the shield electrode 104 is connected to the shield wiring lines 107b and the shield wiring lines 107f that constitute the mesh structure portion, it is possible to suppress the resistance of the shield electrode 104, the shield wiring lines 107b, and the shield wiring lines 107f inside the pixel array 30 to be low.

As illustrated in FIG. 9B, the shield wiring lines 107b, which constitute a part of the mesh structure portion, are located at the same level as the signal lines 109 in the wiring layer 3. The shield wiring line 107b is located between the signal line 109 connected to the pixel 100 corresponding to the pixel area 101 and the signal line 109 connected to the pixel 100 corresponding to the pixel area 101a that are located adjacent to each other. This makes it possible to suppress coupling of the above-mentioned two signal lines 109 with each other by means of the shield wiring line 107b. In the present variation example, the shield wiring line 107b disposed between the above-mentioned two signal lines 109 is an example of a first portion.

In the present variation example, the signal lines 109 are provided in each of the constituent layer 3d and the constituent layer 3c. The signal line 109 provided in the constituent layer 3d and the signal line 109 provided in the constituent layer 3c may be signal lines to which signals different from each other are applied, or may be connected to each other via a non-illustrated contact, etc.

### Fifth Variation Example

Next, an imaging apparatus according to a fifth variation example of the first embodiment will now be described.

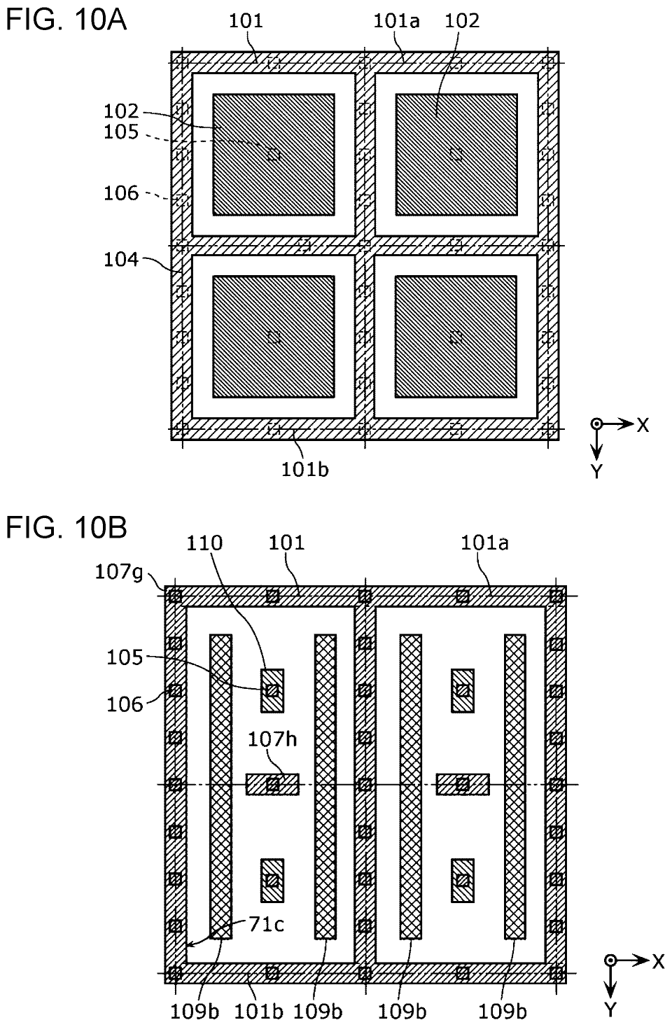

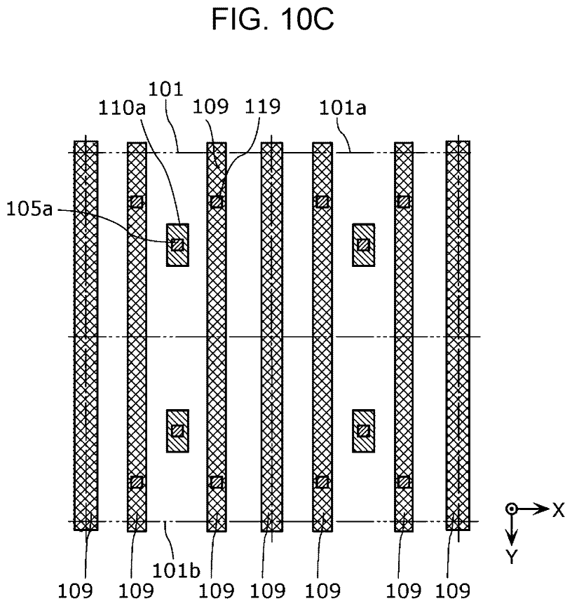

FIG. 10A is a plan view illustrating the layout of electrodes of the pixels 100 according to the present variation example. Each of FIGS. 10B and 10C is a plan view illustrating the layout of wiring lines of the pixels 100 according to the present variation example. Each of FIGS. 10A to 10C illustrates a case where electrodes or wiring lines that are located in an area corresponding to four pixels 100 are viewed in plan. FIG. 10A is a plan view of electrodes disposed on the wiring layer 3 (specifically, the constituent layer 3e of the wiring layer 3). FIG. 10B is a plan view of wiring lines disposed on the constituent layer 3d of the wiring layer 3. FIG. 10C is a plan view of wiring lines disposed on the constituent layer 3c of the wiring layer 3.

As illustrated in FIGS. 10A to 10C, the present variation example is different from the first embodiment in terms of the layout of wiring lines on the constituent layer 3d and the constituent layer 3c of the wiring layer 3. In the present variation example, the wiring layer 3 includes the pixel contacts 105, the FD wiring lines 110, the pixel contacts 105a, the FD wiring lines 110a, the shield contacts 106, a shield wiring line 107g, shield wiring lines 107h, the signal lines 109, signal lines 109b, and the signal line contacts 119.

As illustrated in FIG. 10B, the signal lines 109b, the FD wiring lines 110, the shield wiring line 107g, and the shield wiring lines 107h are embedded in the same constituent layer 3d. As illustrated in FIG. 10C, the signal lines 109 and the FD wiring lines 110a are embedded in the same constituent layer 3c.

Each of the shield wiring line 107g and the shield wiring line(s) 107h is connected to the shield electrode 104 via the shield contact(s) 106. In the present variation example, a wiring line that includes the shield contact 106, the shield wiring line 107g, and the shield wiring line 107h is an example of a first wiring line connected to the shield electrode 104.

The shield wiring line 107g is disposed around the FD wiring lines 110, and is interconnected at a pitch that is twice as great as the pitch pitch_p in the vertical direction and at the pitch pitch_p in the horizontal direction. That is, the shield wiring line 107g has a lattice shape whose pitch in the vertical direction is twice as great as the pitch pitch_p and whose pitch in the horizontal direction is the pitch pitch_p in a plan view.

The first wiring line includes a mesh structure portion that has a pattern like the meshes of a net. The mesh structure portion includes a plurality of openings 71c in a plan view. In the present embodiment, the mesh structure portion is configured as the shield wiring line 107g. Each of the plurality of openings 71c overlaps with the FD wiring lines 110 in a plan view. In the present embodiment, one opening 71c overlaps with two FD wiring lines 110 in a plan view. One opening 71c is disposed for each two or more pixel areas (for example, the pixel areas 101 and 101b) corresponding to a pixel block comprised of two or more pixels 100 among the plurality of pixels 100. In the present variation example, the plurality of pixels 100 includes a plurality of pixel blocks, and there is a one-to-one correspondence between each of the plurality of openings 71c and each of the plurality of pixel blocks. The opening 71c corresponding to a certain pixel block means the opening 71c that overlaps with second wiring lines connected to the respective pixel electrodes 102 of two or more pixels 100 belonging to this certain pixel block.

As described above, in the present variation example, the shield wiring line 107g is disposed each around two FD wiring lines 110, and each of the plurality of openings 71c formed by the shield wiring line 107g overlaps with two FD wiring lines 110. As described above, the shield wiring line 107g exists between mutually adjacent pixel blocks each made up of two pixels 100 arranged in the vertical direction and between the FD wiring lines 110 of mutually adjacent pixels arranged in the horizontal direction; therefore, it is possible to suppress coupling between the mutually adjacent pixel blocks and coupling of the FD wiring lines 110 between the mutually adjacent pixels and suppress electric color mixture. Moreover, since the shield electrode 104 is connected to the shield wiring line 107g that constitutes the mesh structure portion, it is possible to suppress the resistance of the shield electrode 104 and the shield wiring line 107g inside the pixel array 30 to be low. Consequently, it is possible to suppress shading, etc. arising from coupling, etc. of the shield wiring line 107g with the signal line 109, thereby obtaining good dark current characteristics.

The shield wiring line 107h is located between two FD wiring lines 110 overlapping with the opening 71c. This makes it possible to suppress coupling between the two FD wiring lines 110 overlapping with the opening 71c. Any other signal line, power supply line, or ground line may be disposed in place of the shield wiring line 107h between the two FD wiring lines 110 overlapping with the opening 71c.

The signal line 109b overlaps with the opening 71c and is surrounded by the shield wiring line 107g forming the opening 71c. The signal line 109b extends in the vertical direction in such a way as to span from one to the other of two pixel areas located adjacent to each other in the vertical direction (for example, the pixel areas 101 and 101b). The signal line 109b is connected to the signal line 109 via the signal line contacts 119. This makes it possible to make the resistance of the signal line 109 connected to the signal line 109b, which extends in such a way as to span from one to the other of two pixel areas located adjacent to each other in the vertical direction, low. Moreover, since the opening 71c corresponding to two pixel areas located adjacent to each other is formed in the shield wiring line 107g, the freedom of a wiring layout is high; for example, it is possible to easily form the signal line 109b for realizing the low resistance of the signal line 109.

Though the opening 71c of the mesh structure portion (the shield wiring line 107g) is disposed in such a way as to correspond to a pixel block made up of two pixels 100 located adjacent to each other in the vertical direction in the present variation example, the number of the pixels 100 that make up the pixel block corresponding to the opening 71c may be three or more. The pixel block may be a pixel block made up of the pixels 100 located adjacent to each other (one another) in the horizontal direction. The mesh structure portion having an opening corresponding to a pixel block may include a plurality of shield wiring lines disposed in a plurality of constituent layers as in the second variation example of the first embodiment, etc.

### Sixth Variation Example

Next, an imaging apparatus according to a sixth variation example of the first embodiment will now be described.

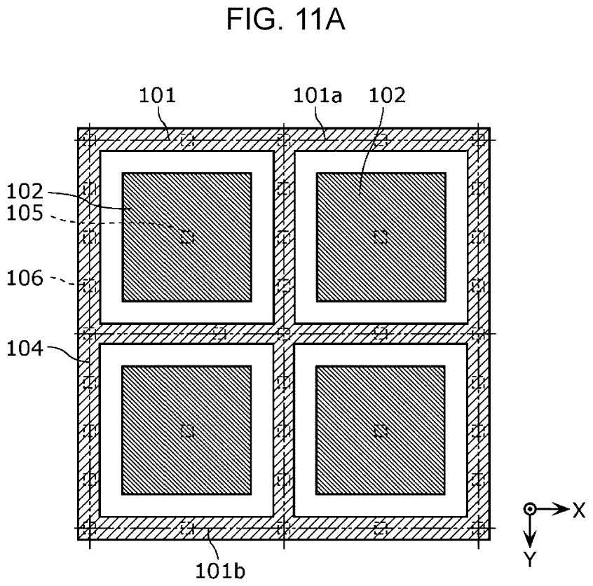

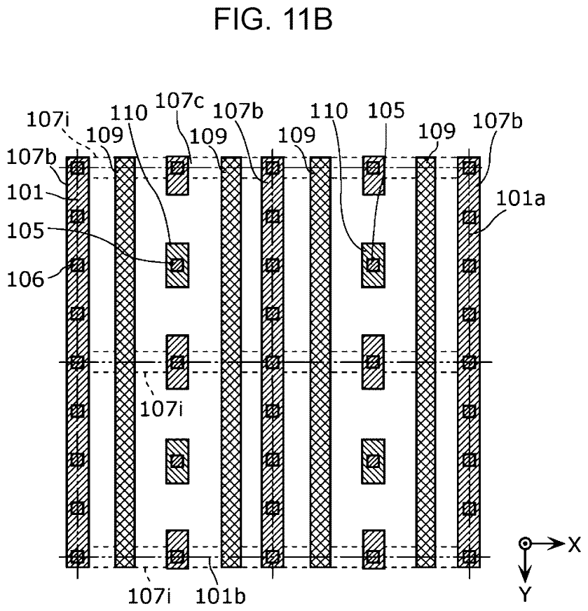

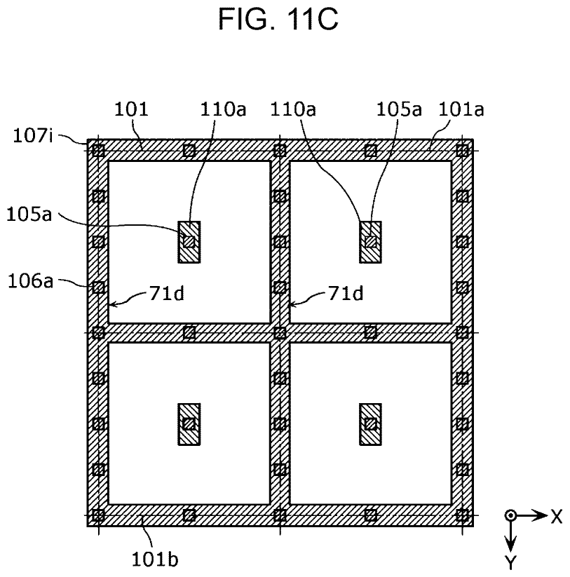

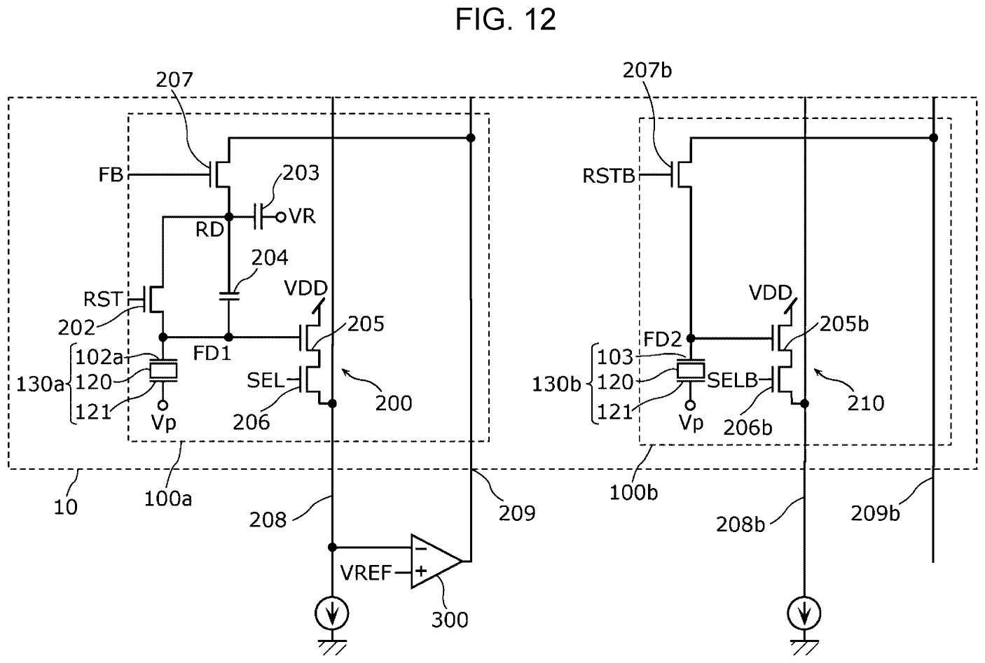

FIG. 11A is a plan view illustrating the layout of electrodes of the pixels 100 according to the present variation example. Each of FIGS. 11B and 11C is a plan view illustrating the layout of wiring lines of the pixels 100 according to the present variation example. Each of FIGS. 11A to 11C illustrates a case where electrodes or wiring lines that are located in an area corresponding to four pixels 100 are viewed in plan. FIG. 11A is a plan view of electrodes disposed on the wiring layer 3 (specifically, the constituent layer 3e of the wiring layer 3). FIG. 11B is a plan view of wiring lines disposed on the constituent layer 3d of the wiring layer 3. FIG. 11C is a plan view of wiring lines disposed on the constituent layer 3c of the wiring layer 3. In FIG. 11B, a shield wiring line 107i disposed below the shield wiring lines 107b is indicated by broken-line illustration.

As illustrated in FIGS. 11A to 11C, the main difference of the present variation example from the second variation example of the first embodiment lies in that the wiring layer 3 includes the shield wiring line 107i in place of the shield wiring lines 107d.

As illustrated in FIG. 11C, the FD wiring lines 110a and the shield wiring line 107i are embedded in the same constituent layer 3c.

The shield wiring line 107i is connected to the shield wiring lines 107b and the shield wiring lines 107c via the shield contacts 106a. The shield wiring line 107i is disposed around the FD wiring line 110a, and is interconnected in the vertical direction and the horizontal direction within a range of the pitch pitch_p. That is, the shield wiring line 107i has a lattice shape having the pitch pitch_p in the vertical direction and the horizontal direction in a plan view. In the present variation example, a wiring line that includes the shield contact 106, the shield wiring line 107b, the shield wiring line 107c, the shield contact 106a, and the shield wiring line 107i is an example of a first wiring line connected to the shield electrode 104.

As illustrated in FIG. 11C, the first wiring line includes a mesh structure portion that has a pattern like the meshes of a net. The mesh structure portion includes a plurality of openings 71d in a plan view. In the present embodiment, the mesh structure portion is configured as the shield wiring line 107i. Each of the plurality of openings 71d overlaps with the FD wiring line 110a in a plan view. In the present embodiment, one opening 71d overlaps with one FD wiring line 110a in a plan view. One opening 71d is disposed for each one pixel area, and there is a one-to-one correspondence between each of the plurality of openings 71d and each of the plurality of pixels 100. As described above, the shield wiring line 107i is disposed around the FD wiring line(s) 110a, and each of the plurality of openings 71d formed by the shield wiring line 107i overlaps with the FD wiring line 110a. Since the shield wiring line 107i exists between the FD wiring lines 110a of mutually adjacent pixels as described above, it is possible to suppress coupling of the FD wiring lines 110a between the mutually adjacent pixels and suppress electric color mixture. Moreover, since the shield electrode 104 is connected to the shield wiring lines 107b and to the shield wiring line 107i constituting the mesh structure portion, it is possible to suppress the resistance of the shield electrode 104, the shield wiring lines 107b, and the shield wiring line 107i inside the pixel array 30 to be low.

The shield wiring line 107i, which constitutes the mesh structure portion, is located at a level that is below the level of the signal lines 109 in the wiring layer 3. Since the signal line 109 is located above the shield wiring line 107i, the distance between the semiconductor substrate 2 and the signal line 109 is long. For this reason, it is possible to reduce the influence of fluctuations in the potential of the signal line 109 on circuitry such as transistors, etc. provided on the semiconductor substrate 2 and thus to reduce noise.

### SECOND EMBODIMENT

Next, an imaging apparatus according to a second embodiment will now be described. In the description of the second embodiment below, the point of difference from the first embodiment and each variation example of the first embodiment will be mainly described, and an explanation of the point of sameness will be omitted or simplified. The same holds true for first and subsequent variation examples of the second embodiment to be described later. In the description of each variation example, the point of difference from the first embodiment, the second embodiment, and other variation examples will be mainly described, and an explanation of the point of sameness will be omitted or simplified.

An imaging apparatus according to the present embodiment includes a unit pixel 10 comprised of a first imaging cell 100a and a second imaging cell 100b described below in place of a unit pixel configured as the pixel 100 in the imaging apparatus 1 described above. That is, an imaging apparatus according to the present embodiment includes a pixel array that includes a plurality of unit pixels 10 arranged in one dimension or in two dimensions on a semiconductor substrate.

FIG. 12 is a diagram illustrating an example of the circuit configuration of the unit pixel 10 according to the present embodiment. The unit pixel 10 includes, inside the identical unit pixel 10, the first imaging cell 100a having a high sensitivity and the second imaging cell 100b whose sensitivity is lower than that of the first imaging cell 100a. In the present embodiment, the first imaging cell 100a is an example of a first pixel, and the second imaging cell 100b is an example of a second pixel. A sensitivity ratio of the first imaging cell 100a to the second imaging cell 100b is greater than one. The sensitivity ratio is a ratio of a proportion of a signal charge storage amount to signal charge saturation capacity of the first imaging cell 100a to this proportion of the second imaging cell 100b when, for example, light that has the same intensity is incident on the first imaging cell 100a and the second imaging cell 100b for the same length of time.

The first imaging cell 100a functions as a low-noise cell responsible for imaging in a case of low illumination. As will be described below, using the first imaging cell 100a and the second imaging cell 100b makes it easier to capture an image of a scene that has a wider dynamic range. The first imaging cell 100a includes a photoelectric conversion unit 130a in place of the photoelectric conversion unit 130 of the pixel 100 according to the first embodiment illustrated in FIG. 2. The photoelectric conversion unit 130a includes a first pixel electrode 102a in place of the pixel electrode 102 of the photoelectric conversion unit 130. The pixel electrode 102 and the first pixel electrode 102a have plan-view shapes different from each other.

The first pixel electrode 102a and a second pixel electrode 103 to be described later are, for example, provided in each of the plurality of unit pixels 10. For example, two unit pixels 10 located adjacent to each other are electrically separated by providing a gap between them. The first pixel electrode 102a is electrically separated from the second pixel electrode 103, too. In the present embodiment, the counter electrode 121 and the photoelectric conversion layer 120 may be formed in such a way as to be shared by all of the plurality of unit pixels 10, or may be formed for each pixel block made up of a few or several unit pixels 10. The counter electrode 121 and the photoelectric conversion layer 120 may be formed in such a way as to be shared by the first imaging cell 100a and the second imaging cell 100b, or may be formed individually for each of the first imaging cell 100a and the second imaging cell 100b.

In the present embodiment, as the voltage Vp applied to the counter electrode 121, a common voltage for all of the plurality of unit pixels 10 may be supplied to each of them. Alternatively, for example, different voltages for respective unit pixel blocks, each of which is made up of a few or several unit pixels 10, may be supplied. Supplying different voltages for respective unit pixel blocks makes it possible to vary the sensitivity of unit pixels. A common voltage for the first imaging cell 100a and the second imaging cell 100b may be supplied as the voltage Vp. Alternatively, voltages that are different from each other may be supplied to the first imaging cell 100a and the second imaging cell 100b.

The second imaging cell 100b functions as a high-saturation cell. The term “high-saturation” means that signal charges that are stored are less susceptible to saturation. That is, the second imaging cell 100b is less likely to suffer charge storage saturation than the first imaging cell 100a by offering at least one of a feature that an amount of signal charges that are trapped is small or a feature that it has a large capacity for storing signal charges. For this reason, the sensitivity of the second imaging cell 100b is lower than that of the first imaging cell 100a.

The second imaging cell 100b includes a photoelectric conversion unit 130b, which converts light into an electric signal, and a detection circuit 210, which is electrically connected to the photoelectric conversion unit 130b and reads out the electric signal generated at the photoelectric conversion unit 130b. Among the components of the second imaging cell 100b, an explanation of each component that has the same function as the counterpart of the first imaging cell 100a will be omitted or simplified.

The photoelectric conversion unit 130b is provided on a substrate such as, for example, a semiconductor substrate, similarly to the photoelectric conversion unit 130a. The photoelectric conversion unit 130b includes the second pixel electrode 103, the counter electrode 121, and the photoelectric conversion layer 120 disposed between the second pixel electrode 103 and the counter electrode 121. The second pixel electrode 103 is connected to a charge storage node FD2.

The detection circuit 210 includes an amplification transistor 205b, a selection transistor 206b, and a reset transistor 207b.

The gate of the amplification transistor 205b is connected to the photoelectric conversion unit 130b. The amplification transistor 205b amplifies the electric signal generated at the photoelectric conversion unit 130b.

One of the source and the drain of the selection transistor 206b is connected to one of the source and the drain of the amplification transistor 205b. The other of the source and the drain of the selection transistor 206b is connected to a vertical signal line 208b. The vertical signal line 208b is connected to the column circuit 312. The gate of the selection transistor 206b is controlled by means of the voltage of an address control line SELB connected to the row scanning circuit 310. The selection transistor 206b selectively outputs the signal amplified by the amplification transistor 205b.

One of the source and the drain of the reset transistor 207b is connected to the charge storage node FD2. The other of the source and the drain of the reset transistor 207b is connected to a reset line 209b. The gate of the reset transistor 207b is controlled by means of the voltage of a reset control line RSTB connected to the row scanning circuit 310. The reset transistor 207b resets (in other words, initializes) the charge storage node FD2 connected to the second pixel electrode 103 of the photoelectric conversion unit 130b.

Since the first imaging cell 100a is responsible for imaging in a dark scene, high-saturation characteristics are not particularly required, although low-noise characteristics are required. On the other hand, since the second imaging cell 100b is responsible for imaging in a bright scene, high-saturation characteristics are required. However, in imaging in a bright scene, the amount of light that enters the photoelectric conversion unit 130b is large, and imaging characteristics are determined based on shot noise; therefore, the second imaging cell 100b is not particularly required to have low-noise characteristics.

Since the first imaging cell 100a includes a feedback circuit, it is possible to significantly suppress noise that occurs when the reset transistor 202 is off.

The second imaging cell 100b may also be configured to include a feedback circuit so as to reduce the noise of the second imaging cell 100b by, for example, providing an inverting amplifier in the second imaging cell 100b and connecting the output terminal of the inverting amplifier to the reset line 209b, similarly to the first imaging cell 100a.

The circuit configuration of the unit pixel 10 is not specifically limited. Any circuit configuration other than the circuit configuration described above, for example, a circuit configuration disclosed in Japanese Unexamined Patent Application Publication No. 2017-135696, may be employed for the unit pixel 10.

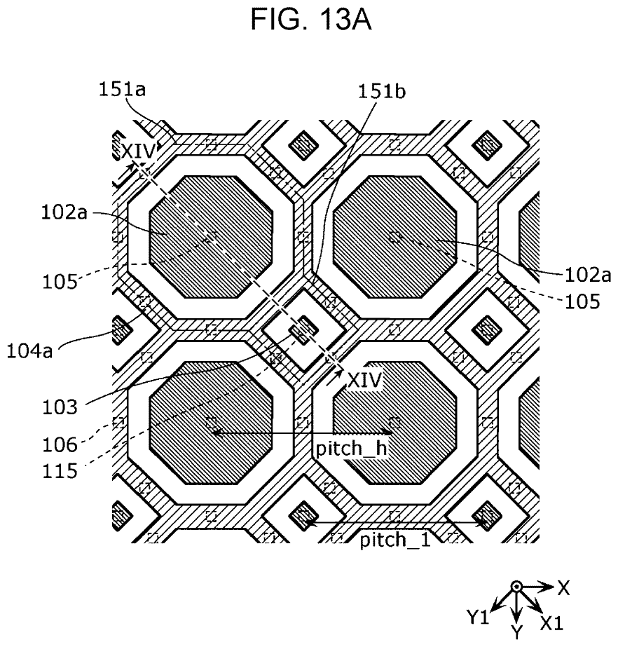

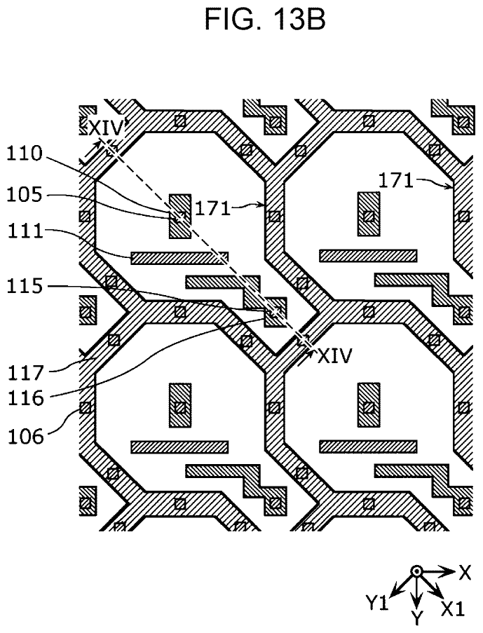

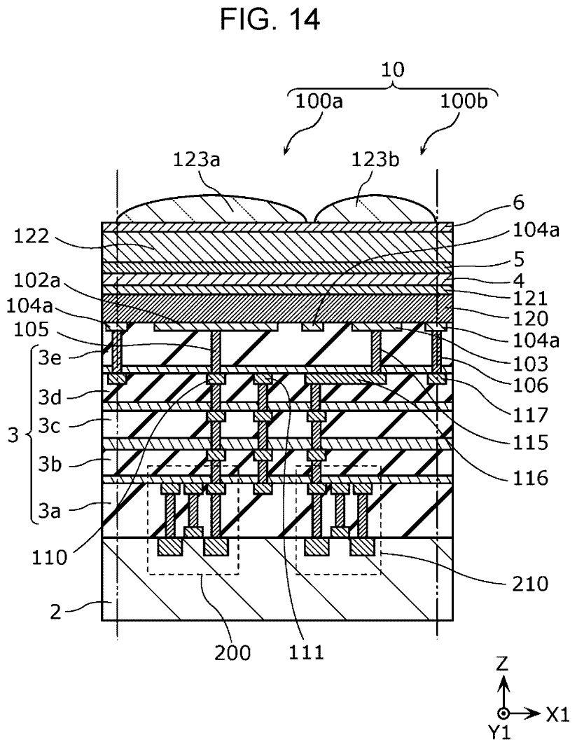

Next, a layout of electrodes, wiring lines, and the like of the unit pixels 10 will now be described. FIG. 13A is a plan view illustrating the layout of electrodes of the unit pixels 10 according to the present embodiment. FIG. 13B is a plan view illustrating the layout of wiring lines of the unit pixels 10 according to the present embodiment. Each of FIGS. 13A and 13B illustrates a case where electrodes or wiring lines that are located in an area corresponding to four unit pixels 10 are viewed in plan. FIG. 14 is a cross-sectional view illustrating the structure of the unit pixel 10 according to the present embodiment. FIG. 14 depicts a cross section taken along the line XIV-XIV of each of FIGS. 13A and 13B. The cross section of an area corresponding to one unit pixel 10 is mainly illustrated in FIG. 14. FIG. 13A is a plan view of electrodes disposed on the wiring layer 3 (specifically, the constituent layer 3e of the wiring layer 3). FIG. 13B is a plan view of wiring lines disposed on the constituent layer 3d of the wiring layer 3.

The areas enclosed by two-dot chain lines in FIG. 13A are pixel areas corresponding to the first imaging cell 100a and the second imaging cell 100b illustrated in FIG. 12. Also in subsequent drawings illustrating the layout of electrodes according to the present embodiment, pixel areas are enclosed by two-dot chain lines. Specifically, a first pixel area 151a is a pixel area corresponding to the first imaging cell 100a, and a second pixel area 151b is a pixel area corresponding to the second imaging cell 100b. The first pixel electrode 102a and a shield electrode 104a are provided in the first pixel area 151a. The second pixel electrode 103 and the shield electrode 104a are provided in the second pixel area 151b.

The shield electrode 104a, which is a common electrode, is disposed around the first pixel electrode 102a, which is provided in the first pixel area 151a, and the second pixel electrode 103, which is provided in the second pixel area 151b. The shield electrode 104a is included in common in the first imaging cell 100a and the second imaging cell 100b. The shield electrode 104a surrounds the first pixel electrode 102a and the second pixel electrode 103.

The shield electrode 104a is located between the first pixel electrode 102a and the second pixel electrode 103. The shield electrode 104a is disposed also between the first pixel electrodes 102a located adjacent to each other and between the second pixel electrodes 103 located adjacent to each other. The shield electrode 104a is included in common in the unit pixels 10 located adjacent to one another. The shield electrode 104a may be formed in such a way as to be shared by all of the unit pixels 10, or may be formed for each unit pixel block made up of a few or several unit pixels 10.

The shield electrode 104a is, for example, connected to a non-illustrated voltage supply circuit, a non-illustrated ground, or the like, and is kept at a predetermined potential. The shield electrode 104a, the first pixel electrodes 102a, and the second pixel electrodes 103 are electrically separated.

Since the shield electrode 104a is disposed between the first pixel electrode 102a and the second pixel electrode 103 as illustrated in FIG. 13A, it is possible to suppress coupling between the first pixel electrode 102a and the second pixel electrode 103 and suppress electric color mixture.

As illustrated in FIGS. 13A to 14, an imaging apparatus according to the present embodiment includes the semiconductor substrate 2, the wiring layer 3 located on the semiconductor substrate 2, a plurality of first pixel electrodes 102a located on the wiring layer 3, a plurality of second pixel electrodes 103 located on the wiring layer 3, the shield electrode 104a located on the wiring layer 3, the counter electrode 121 located above the plurality of first pixel electrodes 102a and the plurality of second pixel electrodes 103 and the shield electrode 104a, the photoelectric conversion layer 120 located between “the plurality of first pixel electrodes 102a and the plurality of second pixel electrodes 103 and the shield electrode 104a” and “the counter electrode 121”, the detection circuits 200, which detect the potentials of the first pixel electrodes 102a, and the detection circuits 210, which detect the potentials of the second pixel electrodes 103. The imaging apparatus according to the present embodiment further includes the buffer layer 4, the sealing layer 5, the color filter 122, the planarization layer 6, and micro lenses 123a and 123b.

The detection circuit 200 and the detection circuit 210 are provided in such a way as to span across the interface between the semiconductor substrate 2 and the wiring layer 3. In FIG. 14, transistors constituting a part of the detection circuit 200 and transistors constituting a part of the detection circuit 210 are illustrated. The first pixel electrodes 102a, the second pixel electrodes 103, and the shield electrode 104a are formed in the upper surface of the wiring layer 3. The first pixel electrode 102a is connected to the detection circuit 200 corresponding thereto via the pixel contact 105 and the FD wiring line 110. The second pixel electrode 103 is connected to the detection circuit 210 corresponding thereto via a pixel contact 115 and an FD wiring line 116. The first pixel electrode 102a, the second pixel electrode 103, and the shield electrode 104a are electrodes for trapping charges generated at the photoelectric conversion layer 120.

The detection circuit 200 is provided correspondingly for each of the plurality of first pixel electrodes 102a. The detection circuit 210 is provided correspondingly for each of the plurality of second pixel electrodes 103. The detection circuits 200 and 210 detect signal charges trapped by the first pixel electrode 102a and the second pixel electrode 103 corresponding thereto, and output signal voltages according to the charges.

Each of the first pixel electrode 102a, the second pixel electrode 103, and the shield electrode 104a is made of a metal material such as, for example, titanium nitride (TIN). Each of the first pixel electrode 102a, the second pixel electrode 103, and the shield electrode 104a may be made of copper (Cu), tungsten (W), titanium (Ti), tantalum (Ta), aluminum (Al), or a compound thereof.

The layer thickness of each of the plurality of first pixel electrodes 102a, the plurality of second pixel electrodes 103, and the shield electrode 104a is uniform. In addition, the upper surface thereof is planarized.

The wiring layer 3 is formed on the semiconductor substrate 2 and includes the plurality of constituent layers 3a to 3e, the pixel contact(s) 105, the FD wiring line(s) 110, the pixel contact(s) 115, the FD wiring line(s) 116, a shield wiring line 117, the shield contact(s) 106, and a shield wiring line(s) 111.

Each of the shield wiring line 117, the shield contact 106, the FD wiring line 110, the FD wiring line 116, the pixel contact 105, and the pixel contact 115 is formed by embedding a conductive material such as, for example, copper (Cu), tungsten (W), titanium (Ti), tantalum (Ta), aluminum (Al), etc. into the wiring layer 3. The electrical resistivity of a material of which each of the shield wiring line 117, the shield contact 106, the FD wiring line 110, the FD wiring line 116, the pixel contact 105, and the pixel contact 115 is made is, for example, lower than the electrical resistivity of a material of which each of the first pixel electrode 102a, the second pixel electrode 103, and the shield electrode 104a is made.

The photoelectric conversion layer 120 lies on the upper surface of the constituent layer 3e, on which the first pixel electrodes 102a, the second pixel electrodes 103, and the shield electrode 104a are disposed. The counter electrode 121, the buffer layer 4, and the sealing layer 5 are stacked in this order on the upper surface of the photoelectric conversion layer 120. The color filter 122 having a transmission wavelength range corresponding to each unit pixel 10 is stacked on the upper surface of the sealing layer 5. On the upper surface of the color filter 122, the micro lens 123a is formed correspondingly for the first pixel electrode 102a, and the micro lens 123b is formed correspondingly for the second pixel electrode 103, with the planarization layer 6 disposed therebetween.

The constituent layer 3e of the wiring layer 3 is interposed between the first pixel electrodes 102a located adjacent to each other and the shield electrode 104a, and between the second pixel electrode 103 and the shield electrode 104a.

The photoelectric conversion layer 120 is sandwiched between “the first pixel electrode 102a, the second pixel electrode 103, and the shield electrode 104a” and “the counter electrode 121”.

The counter electrode 121 is an electrode that is opposed to the first pixel electrode 102a, the second pixel electrode 103, and the shield electrode 104a.

As illustrated in FIGS. 13A, 13B, and 14, the pixel contact 105 for electric connection to the charge storage node FD1 is disposed below the first pixel electrode 102a. The pixel contact 105 is connected to the lower surface of the first pixel electrode 102a. The pixel contact 115 for electric connection to the charge storage node FD2 is disposed below the second pixel electrode 103. The first pixel electrodes 102a are arranged as an array forming a square lattice at a pitch denoted as “pitch_h”. The second pixel electrodes 103 are arranged as an array forming a square lattice at a pitch denoted as “pitch_1”.

In a plan view, the area of the first pixel electrode 102a is larger than that of the second pixel electrode 103. For this reason, it is easier for the first pixel electrode 102a to trap a charge than the second pixel electrode 103. Consequently, the first imaging cell 100a, which corresponds to the first pixel electrode 102a, has a higher sensitivity than the second imaging cell 100b, which corresponds to the second pixel electrode 103.

The length of the pitch pitch_h is, for example, the same as that of the pitch pitch_1. In this case, the resolution of the first imaging cell 100a, which corresponds to the first pixel electrode 102a, is the same as that of the second imaging cell 100b, which corresponds to the second pixel electrode 103.

The first pixel electrode 102a is connected to the FD wiring line 110 via the pixel contact 105. The second pixel electrode 103 is connected to the FD wiring line 116 via the pixel contact 115. In the present embodiment, each of a wiring line that includes the pixel contact 105 and the FD wiring line 110 and a wiring line that includes the pixel contact 115 and the FD wiring line 116 is an example of a second wiring line. The wiring layer 3 includes a plurality of second wiring lines. There is a one-to-one correspondence between each of the plurality of second wiring lines and each of the plurality of first pixel electrodes 102a and each of the plurality of second pixel electrodes 103. In a plan view, for example, the area of the FD wiring line 116 is larger than that of the FD wiring line 110.

The shield contact(s) 106 is disposed below the shield electrode 104a. The shield contact 106 is connected to the lower surface of the shield electrode 104a. The shield electrode 104a is connected to the shield wiring line 117 via the shield contacts 106 in each of a plurality of pixel areas corresponding to a plurality of first imaging cells 100a and a plurality of second imaging cells 100b. The shield wiring line 117 overlaps at least partially with the shield electrode 104a in a plan view. In the present embodiment, a wiring line that includes the shield contact 106 and the shield wiring line 117 is an example of a first wiring line connected to the shield electrode 104a.

The FD wiring line(s) 110, the FD wiring line(s) 116, the shield wiring line 117, and the shield wiring line(s) 111 are embedded in the same constituent layer 3d.

The first wiring line includes a mesh structure portion that has a pattern like the meshes of a net. The mesh structure portion includes a plurality of openings 171 in a plan view. In the present embodiment, the mesh structure portion is configured as the shield wiring line 117. Each of the plurality of openings 171 overlaps with the FD wiring line 110 and the FD wiring line 116 in a plan view. In the present embodiment, in a plan view, one opening 171 overlaps with one FD wiring line 110 connected to the first pixel electrode 102a and with one FD wiring line 116 connected to the second pixel electrode 103 that correspond to one unit pixel 10. That is, there is a one-to-one correspondence between each of the plurality of openings 171 and each of the plurality of unit pixels 10. Since it can also be said that the unit pixel 10 is a pixel block made up of the first imaging cell 100a and the second imaging cell 100b, there is a one-to-one correspondence between each of the plurality of openings 171 and each of the plurality of pixel blocks. One opening 171 corresponds to both one first imaging cell 100a and one second imaging cell 100b.

The shield wiring line 111 is disposed between the FD wiring line 110 and the FD wiring line 116. The shield wiring line 111 is, for example, connected to a non-illustrated voltage supply circuit, a non-illustrated ground, or the like, and is kept at a predetermined potential.

As described above, in the present embodiment, the opening 171 formed by the shield wiring line 117 overlaps with the FD wiring line 110 and the FD wiring line 116. For this reason, unlike the shield electrode 104a, which provides complete isolation between the first pixel electrode 102a and the second pixel electrode 103, the shield wiring line 117 is not disposed between the FD wiring line 110 and the FD wiring line 116, and it is possible to extend the FD wiring line 116 to a region that is wider than the second pixel area 151b and thus to increase the freedom of underlying-stratum connection. Moreover, since the opening 171 overlaps with the FD wiring line 110 and the FD wiring line 116 and since the shield wiring line 117 surrounds the FD wiring line 110 and the FD wiring line 116, it is possible to suppress coupling of the FD wiring lines between the mutually adjacent unit pixels and suppress electric color mixture.

Moreover, since the shield wiring line 111 is disposed between the FD wiring line 110 and the FD wiring line 116, it is possible to suppress coupling of the FD wiring line 110 with the FD wiring line 116 and suppress electric color mixture at the first imaging cell 100a and the second imaging cell 100b.

Moreover, since the shield electrode 104a is connected to the shield wiring line 117 that constitutes the mesh structure portion, it is possible to suppress the resistance of the shield electrode 104a and the shield wiring line 117 inside the pixel array to be low. Consequently, it is possible to suppress shading, etc. arising from coupling, thereby obtaining good dark current characteristics. With the present embodiment described above, a noise-reduced imaging apparatus is realized.

### First Variation Example

Next, an imaging apparatus according to a first variation example of the second embodiment will now be described.

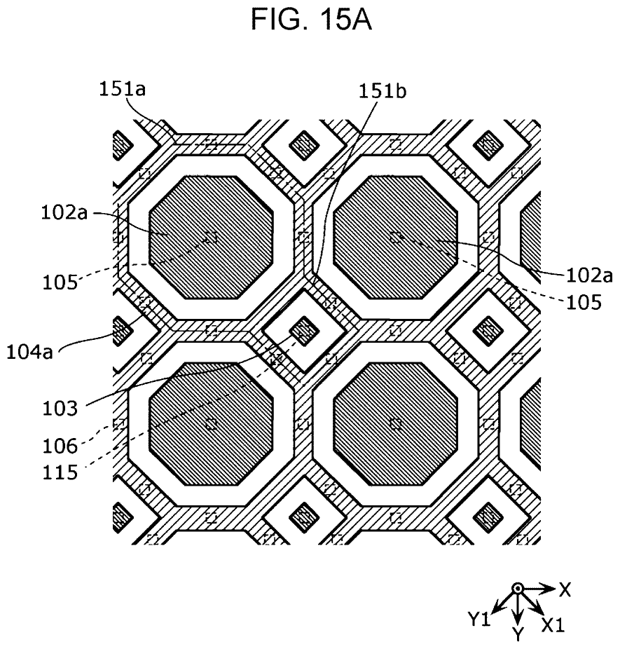

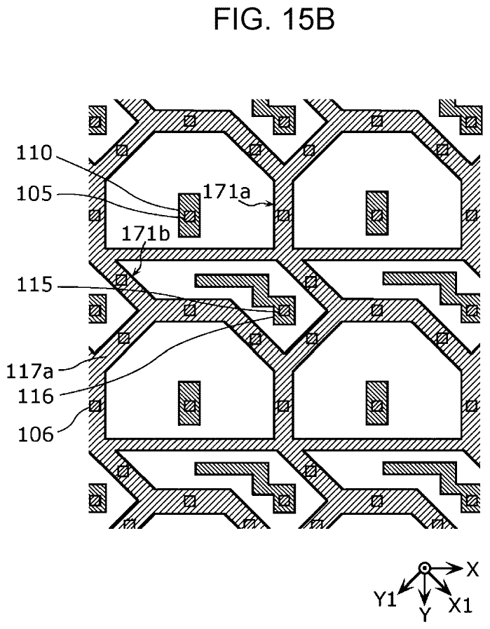

FIG. 15A is a plan view illustrating the layout of electrodes of the unit pixels 10 according to the present variation example. FIG. 15B is a plan view illustrating the layout of wiring lines of the unit pixels 10 according to the present variation example. Each of FIGS. 15A and 15B illustrates a case where electrodes or wiring lines that are located in an area corresponding to four unit pixels 10 are viewed in plan. FIG. 15A is a plan view of electrodes disposed on the wiring layer 3 (specifically, the constituent layer 3e of the wiring layer 3). FIG. 15B is a plan view of wiring lines disposed on the constituent layer 3d of the wiring layer 3.

As illustrated in FIGS. 15A and 15B, the main difference of the present variation example from the second embodiment lies in that the wiring layer 3 does not include the shield wiring lines 111, and includes a shield wiring line 117a in place of the shield wiring line 117. In the present variation example, the wiring layer 3 includes the pixel contacts 105, the FD wiring lines 110, the pixel contacts 115, the FD wiring lines 116, the shield contacts 106, and the shield wiring line 117a.

As illustrated in FIG. 15B, the FD wiring lines 110, the FD wiring lines 116, and the shield wiring line 117a are embedded in the same constituent layer 3d.

The shield wiring line 117a is connected to the shield electrode 104a via the shield contacts 106. In the present variation example, a wiring line that includes the shield wiring line 117a and the shield contact 106 is an example of a first wiring line connected to the shield electrode 104a. The shield wiring line 117a is disposed between the FD wiring lines 110 located adjacent to each other, between the FD wiring lines 116 located adjacent to each other, and between the FD wiring line 110 and the FD wiring line 116 located adjacent to each other.

The first wiring line includes a mesh structure portion that has a pattern like the meshes of a net. In a plan view, the mesh structure portion includes, as a plurality of openings, a plurality of openings 171a and a plurality of openings 171b. In the present variation example, the mesh structure portion is configured as the shield wiring line 117a. Each of the plurality of openings 171a overlaps with the FD wiring line 110 in a plan view. In the present variation example, one opening 171a overlaps with one FD wiring line 110 connected to the first pixel electrode 102a. That is, there is a one-to-one correspondence between each of the plurality of openings 171a and each of the plurality of first imaging cells 100a. Each of the plurality of openings 171b overlaps with the FD wiring line 116 in a plan view. In the present variation example, one opening 171b overlaps with one FD wiring line 116 connected to the second pixel electrode 103. That is, there is a one-to-one correspondence between each of the plurality of openings 171b and each of the plurality of second imaging cells 100b. Since the opening 171a overlaps with the FD wiring line 110 and since the opening 171b overlaps with the FD wiring line 116 as described above, it is possible to suppress coupling of the FD wiring lines between the mutually adjacent pixels and between the mutually adjacent unit pixels by means of the shield wiring line 117a and thus suppress electric color mixture.

As illustrated in FIGS. 15A and 15B, in a plan view, the ratio of the area of the first pixel electrode 102a to the area of the second pixel electrode 103 is greater than the ratio of the area of the opening 171a corresponding to the first imaging cell 100a to the area of the opening 171b corresponding to the second imaging cell 100b. Since this increases the size of the opening 171b overlapping with the FD wiring line 116, it is possible to suppress coupling of the FD wiring line 116 with the FD wiring line 110 and suppress electric color mixture by surrounding the FD wiring line 116 by the shield wiring line 117a without using any other wiring while keeping the freedom of underlying-stratum connection of the FD wiring line 116 high.

Moreover, since the shield electrode 104a is connected to the shield wiring line 117a that constitutes the mesh structure portion, it is possible to suppress the resistance of the shield electrode 104a and the shield wiring line 117a inside the pixel array to be low.

### Second Variation Example

Next, an imaging apparatus according to a second variation example of the second embodiment will now be described.

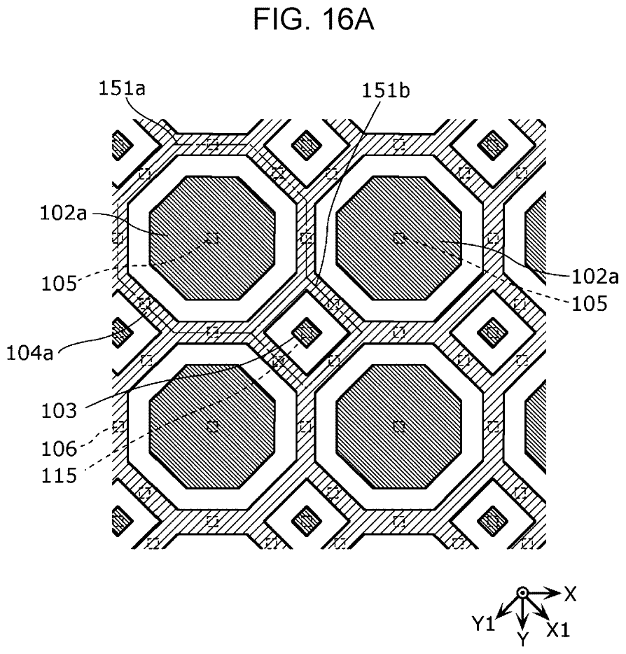

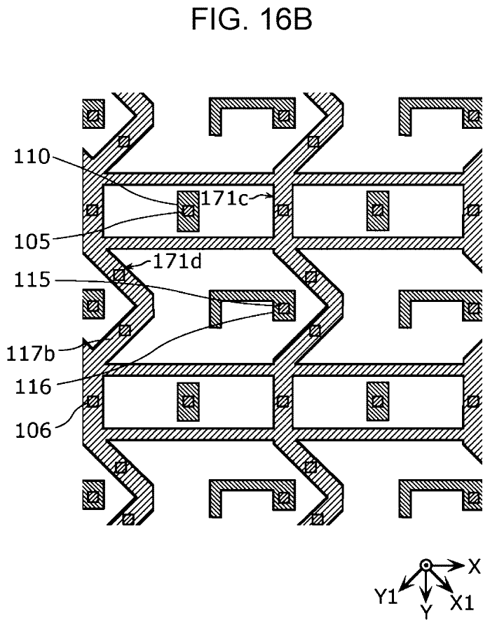

FIG. 16A is a plan view illustrating the layout of electrodes of the unit pixels 10 according to the present variation example. FIG. 16B is a plan view illustrating the layout of wiring lines of the unit pixels 10 according to the present variation example. Each of FIGS. 16A and 16B illustrates a case where electrodes or wiring lines that are located in an area corresponding to four unit pixels 10 are viewed in plan. FIG. 16A is a plan view of electrodes disposed on the wiring layer 3 (specifically, the constituent layer 3e of the wiring layer 3). FIG. 16B is a plan view of wiring lines disposed on the constituent layer 3d of the wiring layer 3.

As illustrated in FIGS. 16A and 16B, the main difference of the present variation example from the second embodiment lies in that the wiring layer 3 does not include the shield wiring lines 111, and includes a shield wiring line 117b in place of the shield wiring line 117. In the present variation example, the wiring layer 3 includes the pixel contacts 105, the FD wiring lines 110, the pixel contacts 115, the FD wiring lines 116, the shield contacts 106, and the shield wiring line 117b.

As illustrated in FIG. 16B, the FD wiring lines 110, the FD wiring lines 116, and the shield wiring line 117b are embedded in the same constituent layer 3d.

The shield wiring line 117b is connected to the shield electrode 104a via the shield contacts 106. In the present variation example, a wiring line that includes the shield wiring line 117b and the shield contact 106 is an example of a first wiring line connected to the shield electrode 104a. The shield wiring line 117b is disposed between the FD wiring lines 110 located adjacent to each other, between the FD wiring lines 116 located adjacent to each other, and between the FD wiring line 110 and the FD wiring line 116 located adjacent to each other.

The first wiring line includes a mesh structure portion that has a pattern like the meshes of a net. In a plan view, the mesh structure portion includes, as a plurality of openings, a plurality of openings 171c and a plurality of openings 171d. In the present variation example, the mesh structure portion is configured as the shield wiring line 117b. Each of the plurality of openings 171c overlaps with the FD wiring line 110 in a plan view. In the present variation example, one opening 171c overlaps with one FD wiring line 110 connected to the first pixel electrode 102a. That is, there is a one-to-one correspondence between each of the plurality of openings 171c and each of the plurality of first imaging cells 100a. Each of the plurality of openings 171d overlaps with the FD wiring line 116 in a plan view. In the present variation example, one opening 171d overlaps with one FD wiring line 116 connected to the second pixel electrode 103. That is, there is a one-to-one correspondence between each of the plurality of openings 171d and each of the plurality of second imaging cells 100b. Since the opening 171c overlaps with the FD wiring line 110 and since the opening 171d overlaps with the FD wiring line 116 as described above, it is possible to suppress coupling of the FD wiring lines between the mutually adjacent pixels and between the mutually adjacent unit pixels by means of the shield wiring line 117b and thus suppress electric color mixture.

As illustrated in FIGS. 16A and 16B, in a plan view, the area of the opening 171d corresponding to the second imaging cell 100b is larger than the area of the opening 171c corresponding to the first imaging cell 100a. Since this increases the size of the opening 171d overlapping with the FD wiring line 116, it is possible to suppress coupling of the FD wiring line 116 with the FD wiring line 110 and suppress electric color mixture by surrounding the FD wiring line 116 by the shield wiring line 117b without using any other wiring while keeping the freedom of underlying-stratum connection of the FD wiring line 116 high.

Moreover, since the shield electrode 104a is connected to the shield wiring line 117b that constitutes the mesh structure portion, it is possible to suppress the resistance of the shield electrode 104a and the shield wiring line 117b inside the pixel array to be low.

### Third Variation Example

Next, an imaging apparatus according to a third variation example of the second embodiment will now be described.

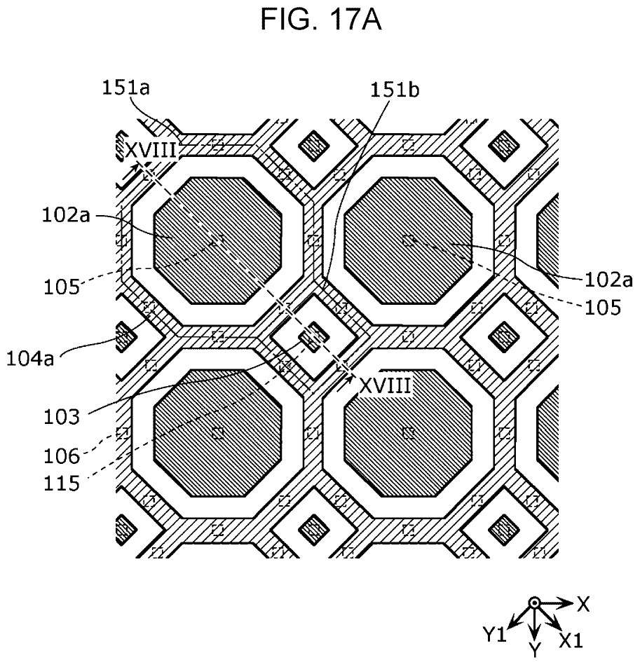

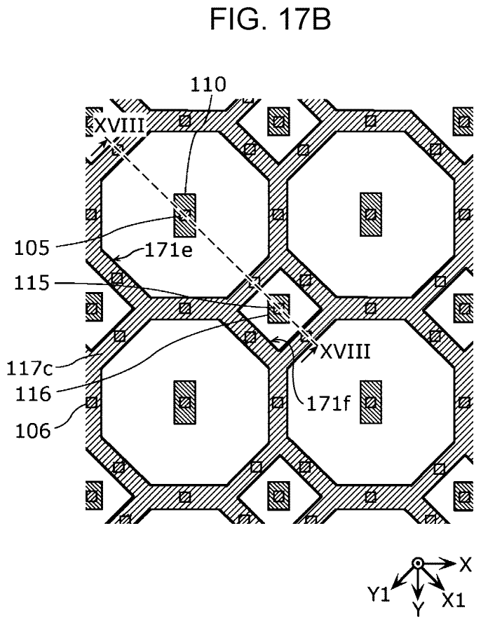

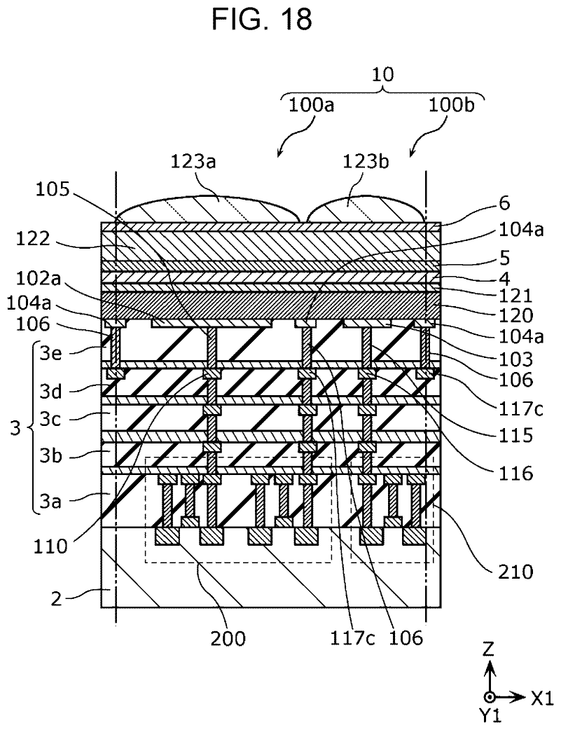

FIG. 17A is a plan view illustrating the layout of electrodes of the unit pixels 10 according to the present variation example. FIG. 17B is a plan view illustrating the layout of wiring lines of the unit pixels 10 according to the present variation example. Each of FIGS. 17A and 17B illustrates a case where electrodes or wiring lines that are located in an area corresponding to four unit pixels 10 are viewed in plan. FIG. 18 is a cross-sectional view illustrating the structure of the unit pixel 10 according to the present variation example. FIG. 18 depicts a cross section taken along the line XVIII-XVIII of each of FIGS. 17A and 17B. The cross section of an area corresponding to one unit pixel 10 is mainly illustrated in FIG. 18.

As illustrated in FIGS. 17A to 18, the main difference of the present variation example from the second embodiment lies in that the wiring layer 3 does not include the shield wiring lines 111, and includes a shield wiring line 117c in place of the shield wiring line 117. In the present variation example, the wiring layer 3 includes the pixel contacts 105, the FD wiring lines 110, the pixel contacts 115, the FD wiring lines 116, the shield wiring line 117c, and the shield contacts 106.

As illustrated in FIGS. 17B and 18, the FD wiring lines 110, the FD wiring lines 116, and the shield wiring line 117c are embedded in the same constituent layer 3d.

The shield wiring line 117c is connected to the shield electrode 104a via the shield contacts 106. In the present variation example, the shield contact 106 is disposed also between the pixel contact 105 and the pixel contact 115. In the present variation example, a wiring line that includes the shield wiring line 117c and the shield contact 106 is an example of a first wiring line connected to the shield electrode 104a. The shield wiring line 117c is disposed between the FD wiring lines 110 located adjacent to each other, between the FD wiring lines 116 located adjacent to each other, and between the FD wiring line 110 and the FD wiring line 116 located adjacent to each other. As illustrated in FIGS. 17A to 18, the shield wiring line 117c has the same shape and the same layout as those of the shield electrode 104a in a plan view.

The first wiring line includes a mesh structure portion that has a pattern like the meshes of a net. In a plan view, the mesh structure portion includes, as a plurality of openings, a plurality of openings 171e and a plurality of openings 171f. In the present variation example, the mesh structure portion is configured as the shield wiring line 117c. Each of the plurality of openings 171e overlaps with the FD wiring line 110 in a plan view. In the present variation example, one opening 171e overlaps with one FD wiring line 110 connected to the first pixel electrode 102a. That is, there is a one-to-one correspondence between each of the plurality of openings 171e and each of the plurality of first imaging cells 100a. Each of the plurality of openings 171f overlaps with the FD wiring line 116 in a plan view. In the present variation example, one opening 171f overlaps with one FD wiring line 116 connected to the second pixel electrode 103. That is, there is a one-to-one correspondence between each of the plurality of openings 171f and each of the plurality of second imaging cells 100b. Since the opening 171e overlaps with the FD wiring line 110 and since the opening 171f overlaps with the FD wiring line 116 as described above, it is possible to suppress coupling of the FD wiring lines between the mutually adjacent pixels and between the mutually adjacent unit pixels by means of the shield wiring line 117c and thus suppress electric color mixture.

Moreover, since the shield electrode 104a is connected to the shield wiring line 117c that constitutes the mesh structure portion, it is possible to suppress the resistance of the shield electrode 104a and the shield wiring line 117c inside the pixel array to be low.

### Third Embodiment

Next, a third embodiment will now be described. In the third embodiment, a camera system that includes the imaging apparatus 1 according to the first embodiment will be described.

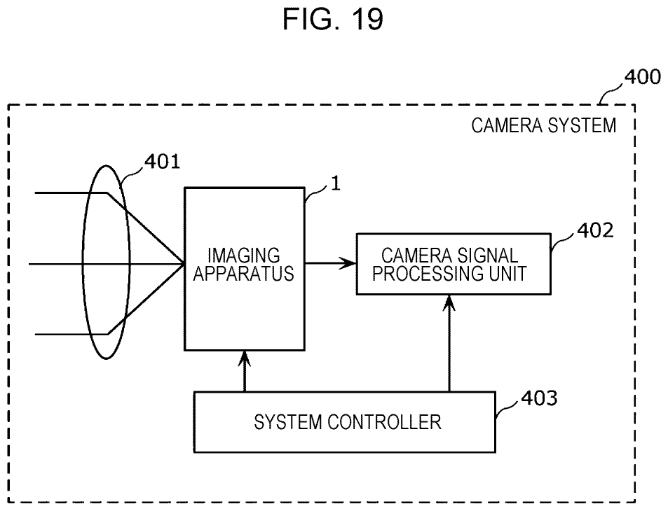

FIG. 19 is a block diagram that illustrates an example of the configuration of a camera system 400 according to the present embodiment.

As illustrated in FIG. 19, the camera system 400 according to the present embodiment includes the imaging apparatus 1 according to the foregoing embodiment, an optical system 401 such as a lens for condensing light, a camera signal processing unit 402 for performing signal processing on data captured by the imaging apparatus 1 and outputting the result of the processing as an image or as data, and a system controller 403 for controlling the imaging apparatus 1 and the camera signal processing unit 402.

The optical system 401 is a lens or the like for condensing light onto the imaging area of the imaging apparatus 1.

The camera signal processing unit 402 functions as a signal processing circuit that processes a signal outputted from the imaging apparatus 1. The camera signal processing unit 402 performs processing including, for example, gamma correction, color interpolation, spatial interpolation, automatic white balancing, distance measurement computation, wavelength information separation, and the like. The camera signal processing unit 402 can be embodied as, for example, a digital signal processor (DSP).

The system controller 403 performs overall control on the camera system 400.

The system controller 403 can be embodied as, for example, a processor, a micro computer, or the like, with a program stored therein.

The imaging apparatus 1 according to the first embodiment is used in the camera system 400 according to the present embodiment. By this means, it is possible to provide a camera system that includes a noise-reduced multilayer-type imaging apparatus that realizes good dark current characteristics while suppressing color mixture between mutually adjacent pixels.

The camera system 400 may include, in place of the imaging apparatus 1 according to the first embodiment, any of an imaging apparatus according to each variation example of the first embodiment, an imaging apparatus according to the second embodiment, and an imaging apparatus according to each variation example of the second embodiment.

### Other Embodiments

Although an imaging apparatus and a camera system according to one or more modes have been described above on the basis of each embodiment and each variation example, the present disclosure shall not be construed to be limited to these embodiments and variation examples. Modes formulated by applying various kinds of modification which a person skilled in the art can think of to each embodiment and each variation example and modes formulated by combining components disclosed in different embodiments and different variation examples are also encompassed within the scope of the present disclosure, unless the formulated mode is a deviation from the essence of the present disclosure.

Various kinds of alteration, replacement, addition, omission, and the like can be performed within the scope of appended claims or equivalents thereof on each embodiment and each variation example having been described above.

An imaging apparatus according to the present disclosure can be used for various camera systems and various sensor systems such as a digital still camera, a medical camera, a surveillance camera, a vehicle-mounted camera, a digital single-lens reflex camera, a digital mirrorless single-lens camera, and the like.

What is claimed is:

1. An imaging device including pixels, the imaging device comprising:
a semiconductor substrate;
a wiring layer located on the semiconductor substrate and including an insulation layer and wiring lines;
pixel electrodes located on the wiring layer, each of the pixel electrodes corresponding one-to-one to each of the pixels;
a shield electrode located on the wiring layer and located between the pixel electrodes;
a counter electrode located above the pixel electrodes and the shield electrode; and
a photoelectric conversion layer located between (A) the pixel electrodes and the shield electrode and (B) the counter electrode, wherein
the wiring layer includes a first wiring line including a mesh structure portion, and second wiring lines, each of the second lines corresponding one-to-one to each of the pixel electrodes and being connected to corresponding one of the pixel electrodes,
the first wiring line is connected to the shield electrode, and
the mesh structure portion includes openings each overlapping with at least one of the second wiring lines in a plan view.

2. The imaging device according to claim 1, wherein
each of the openings corresponds one-to-one to each of the pixels.

3. The imaging device according to claim 1, wherein
the pixels include pixel blocks each comprised of two or more pixels among the pixels, and
each of the openings corresponds one-to-one to each of the pixel blocks.

4. The imaging device according to claim 1, wherein
the mesh structure portion overlaps at least partially with the shield electrode in a plan view.

5. The imaging device according to claim 1, wherein
the first wiring line is connected to the shield electrode in each of the pixels.

6. The imaging device according to claim 1, wherein
an electrical resistivity of a material of which the first wiring line is made is lower than an electrical resistivity of a material of which the shield electrode is made.

7. The imaging device according to claim 1, wherein
the pixels include a first pixel,
the wiring layer includes a first signal line connected to the first pixel, and
at least a part of the mesh structure portion is located at a level that is above a level of the first signal line in the wiring layer.

8. The imaging device according to claim 1, wherein
the pixels include a first pixel,
the wiring layer includes a first signal line connected to the first pixel, and
at least a part of the mesh structure portion is located at a level that is below a level of the first signal line in the wiring layer.

9. The imaging device according to claim 1, wherein
the pixels include a first pixel,
the wiring layer includes a first signal line connected to the first pixel, and
at least a part of the mesh structure portion is located at a same level as the first signal line in the wiring layer.

10. The imaging device according to claim 1, wherein
a part of the mesh structure portion and another part of the mesh structure portion are located at levels different from each other in the wiring layer.

11. The imaging device according to claim 1, wherein
the pixels include a first pixel and a second pixel,
the wiring layer includes a first signal line connected to the first pixel and a second signal line located at a same level as the first signal line and connected to the second pixel,
the first wiring line includes a first portion located at the same level as the first signal line and the second signal line, and
the first portion is located between the first signal line and the second signal line.

12. The imaging device according to claim 1, wherein
the pixels include a first pixel,
the wiring layer includes a first signal line located at a same level as a part of the second wiring line and connected to the first pixel,
the first wiring line includes a second portion located at the same level as the first signal line and the part of the second wiring line, and
the second portion is located between the first signal line and the part of the second wiring line.

13. The imaging device according to claim 1, wherein
the pixels include a first pixel and a second pixel,
the pixel electrodes include a first pixel electrode corresponding to the first pixel and a second pixel electrode corresponding to the second pixel, and
an area of the first pixel electrode is larger than an area of the second pixel electrode in a plan view.

14. The imaging device according to claim 13, wherein
in a plan view, a ratio of the area of the first pixel electrode to the area of the second pixel electrode is greater than a ratio of an area of an opening corresponding to the first pixel among the openings to an area of an opening corresponding to the second pixel among the openings.

15. The imaging device according to claim 1, wherein
the first wiring line includes a contact located between the shield electrode and the mesh structure portion, and
the shield electrode is connected to the mesh structure portion via the contact.

16. A camera system, comprising:
the imaging device according to claim 1.
